(19) United States
(12) Patent Application Publication
(10) Pub. No.: US 2026/0271389 A1
(43) Pub. Date: Sep. 10, 2026

(54) SEMICONDUCTOR STRUCTURE AND METHOD OF FORMING THEREOF

(71) Applicant: TAIWAN SEMICONDUCTOR MANUFACTURING COMPANY, LTD., Hsinchu (TW)

(72) Inventors: Ta-Chun LIN, Hsinchu (TW); Ming-Heng TSAI, Taipei City (TW); Hong-Chih CHEN, Changhua County (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 19/072,461

(22) Filed: Mar. 6, 2025

(51) Int. Cl. H10D 84/85; H10D 30/00; H10D 30/01; H10D 30/43; H10D 62/10; H10D 62/13; H10D 64/23; H10D 64/68; H10D 84/01

(52) U.S. Cl. CPC H10D 84/851; H10D 30/014; H10D 30/0191; H10D 30/43; H10D 30/502; H10D 62/121; H10D 62/151; H10D 64/693; H10D 84/0186; H10D 64/256; H10D 84/856

(57) ABSTRACT

A method includes a number of operations. A first channel region and a second channel region are formed over the substrate. An isolation feature is formed over the substrate and between the first and second channel regions. A first source/drain feature is formed and interfaces a sidewall of the first channel region. A source/drain contact is formed over the first source/drain feature. A second source/drain feature is formed and interfaces a sidewall of the second channel region, wherein the second source/drain feature is free of any source/drain contact. An etch stop layer is formed and continuously extends from over the first source/drain feature to over the second source/drain feature. An interlayer dielectric (ILD) layer is formed over the etch stop layer, wherein a top surface of the isolation feature is spaced apart from the ILD layer by the etch stop layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2 through 25C are top views and cross-sectional views of intermediate stages in the manufacturing of GAA-FETs, in accordance with some embodiments.

FIG. 26 illustrates a circuit diagram, in accordance with some embodiments.

FIGS. 27A and 27B illustrate a top view and a cross-sectional view of a semiconductor structure, in accordance with some embodiments.

FIGS. 28A and 28B illustrate a top view and a cross-sectional view of a semiconductor structure, in accordance with some embodiments.

FIGS. 29A and 29B illustrate a top view and a cross-sectional view of a semiconductor structure, in accordance with some embodiments.

FIGS. 30A and 30B illustrate a top view and a cross-sectional view of a semiconductor structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is generally related to integrated circuit (IC) structures and methods of forming the same, and more particularly to fabricating gate-all-around (GAA) transistors, planar transistors, and/or fin field effect transistors (FinFET). It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

Various embodiments relate to a semiconductor structure with a cascade device, which includes transistors sharing a common source/drain region. In some embodiments, the semiconductor structure may include a plurality of transistors, and the cascade device is the transistors connected in series with the common source/drain region. For example, an NAND structure or an NOR structure may include the cascade device. In one or more embodiments, the cascade device is free of source/drain contact to reduce series resistance. The source/drain contact may be formed on and deeply extend within the transistors except for the transistors of the cascade device to reduce contact resistance. In some embodiments, the structure can be GAA, Fork-sheet, or CFET.

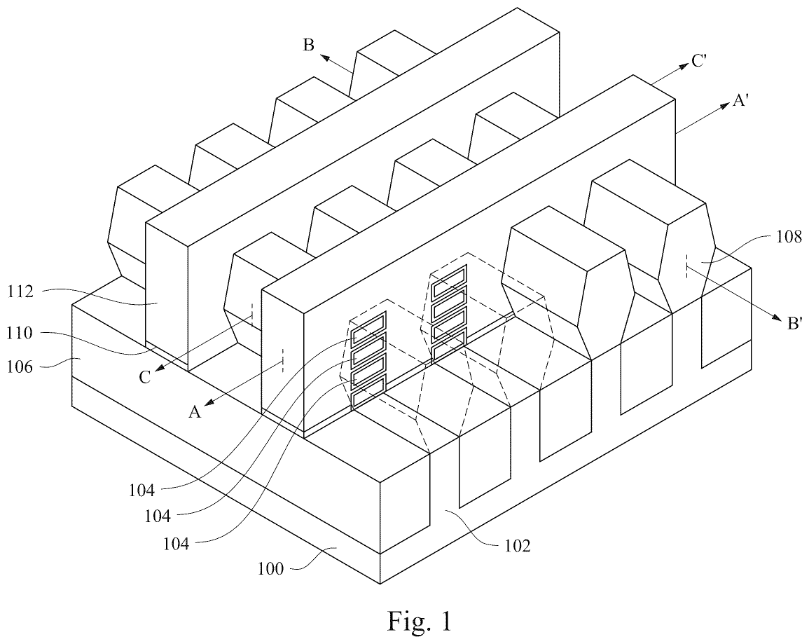

FIG. 1 illustrates an example of GAA-FETs (e.g., nanowire FETs, nanosheet FETs, or the like) in a three-dimensional view, in accordance with some embodiments. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions for the GAA-FETs. The nanostructure 104 may include p-type nanostructures, n-type nanostructures, or a combination thereof. Isolation regions 106 are disposed between adjacent fins 102, which may protrude above and from between neighboring isolation regions 106. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 is illustrated as being single, continuous materials with the substrate 100, the bottom portion of the fins 102 and/or the substrate 100 may comprise a single material or a plurality of materials. In this context, the fins 102 refer to the portions extending between the neighboring isolation regions 106.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectric layers 110 and the gate electrodes 112.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. Cross-section C-C′ is parallel to cross-section A-A′ and extends through epitaxial source/drain regions of the GAA-FETs. Subsequent figures refer to these reference cross-sections for clarity.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

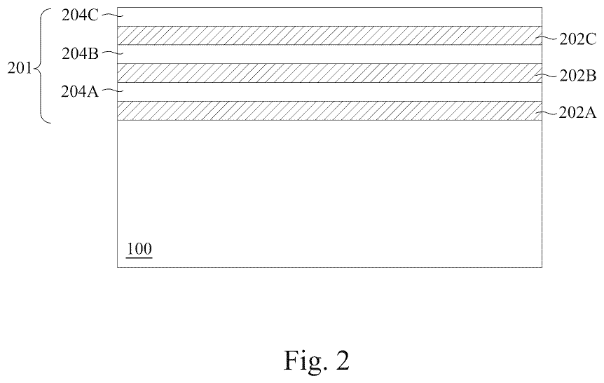

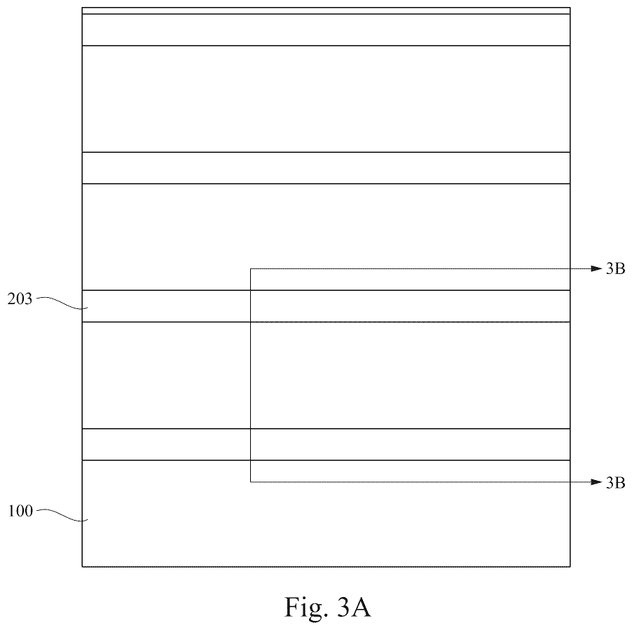

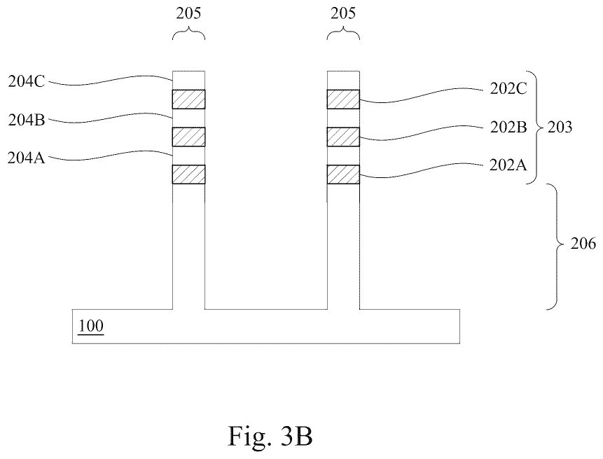

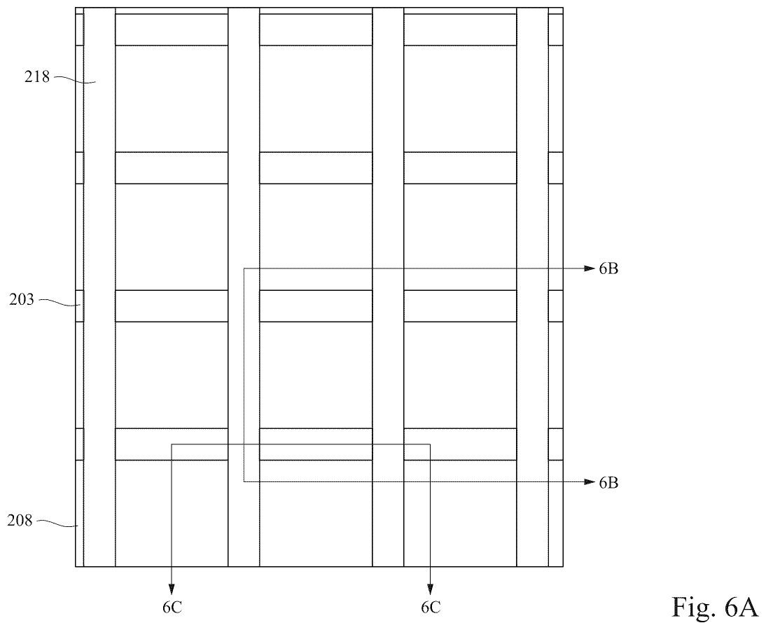

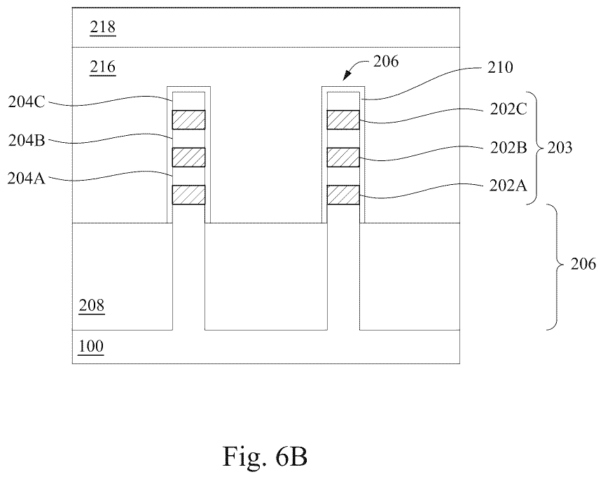

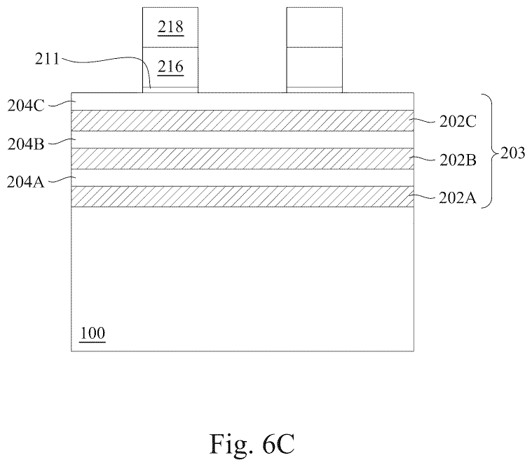

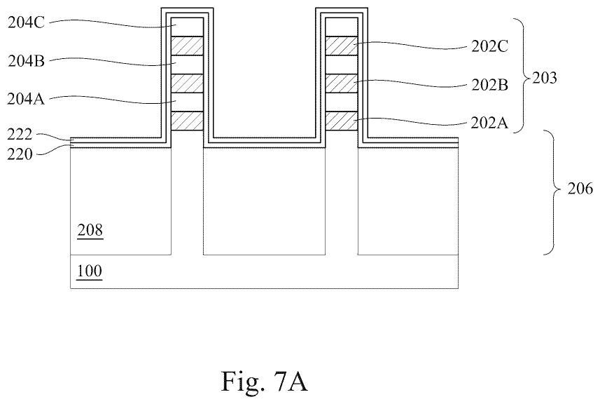

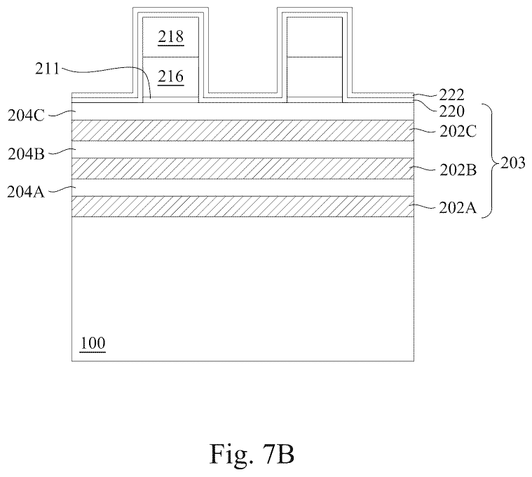

FIGS. 2 through 25B are top views and cross-sectional views of intermediate stages in the manufacturing of GAA-FETs, in accordance with some embodiments. FIGS. 3A, 4A, 6A, 8A, 17A, 17D, 18A, 19A, 24A and 25A illustrate schematic top views of intermediate stages in the manufacturing of GAA-FETs, in accordance with some embodiments. FIGS. 2, 3B, 4B, 4C, 4D, 5, 6B, 13A, 14A, 15A, 16A, 17B and 18B illustrate reference cross-section A-A′ illustrated in FIG. 1 that extends through a gate region along a longitudinal axis of the gate region. FIGS. 6B, 7B, 8C, 9B, 10B, 11B, 11C, 12B, 12D, 13B, 14B, 15B, 16B, 17C, 19B, 20A, 21A, 22A, 23A, 24B and 25B illustrate cross-sectional views of reference cross-section B-B′ illustrated in FIG. 1 that extends through a fin along a longitudinal axis of the fin. FIGS. 7A, 8B, 9A, 10A, 11A, 12A, 12C, 13C, 17D, 19C, 20B, 21B, 22B, 23B, 24C and 25C illustrate reference cross-section C-C′ illustrated in FIG. 1 that extends through source/drain regions along the longitudinal direction of the gate region.

Reference is made to FIG. 2. FIG. 2 illustrates forming a multi-layer stack 201 over a substrate 100, in accordance with some embodiments.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

Reference is made to FIGS. 3A and 3B. FIGS. 3A and 3B illustrate forming fin structures 206 and nanostructures 203, in accordance with some embodiments. FIG. 3B illustrates a cross-sectional view along the cross-section 3B-3B in FIG. 3A.

As illustrated in FIGS. 3A and 3B, fin structures 206 are formed in the substrate 100 and nanostructures 203 are formed in the multi-layer stack 201, in accordance with some embodiments. Each fin structure 206 and corresponding nanostructures 203 directly above the fin structure 206 can be collectively referred to as an active region 205. In some embodiments, the nanostructures 203 and the fin structures 206 may be formed in the multi-layer stack 201 and the substrate 100, respectively, by etching trenches in the multi-layer stack 201 and the substrate 100. The fin structure 206 can be referred to as base regions of the substrate 100. Each fin structure 206 and overlying nanostructures 203 can be collectively referred to as a semiconductor fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

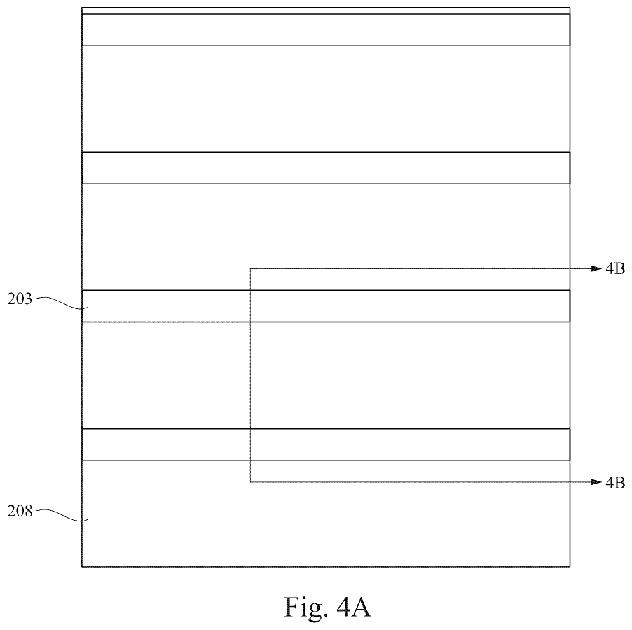

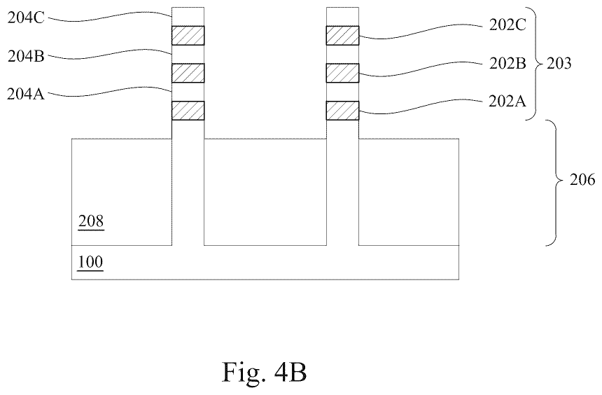

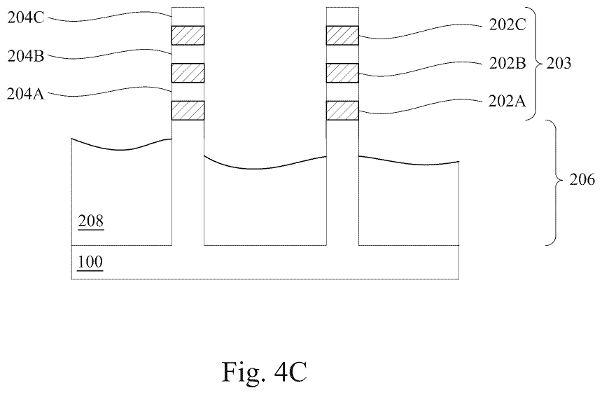

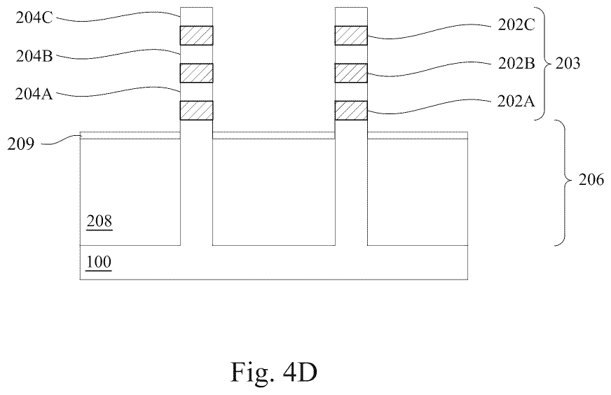

Reference is made to FIGS. 4A and 4B. FIGS. 4A and 4B illustrate formation of shallow trench isolation (STI) regions 208, in accordance with some embodiments. FIG. 4B illustrates a cross-sectional view along the cross-section 4B-4B in FIG. 4A.

In FIGS. 4A and 4B, shallow trench isolation (STI) regions 208 are formed adjacent the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

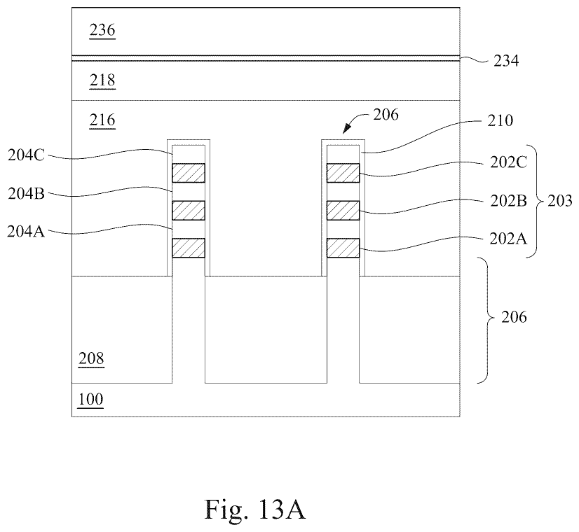

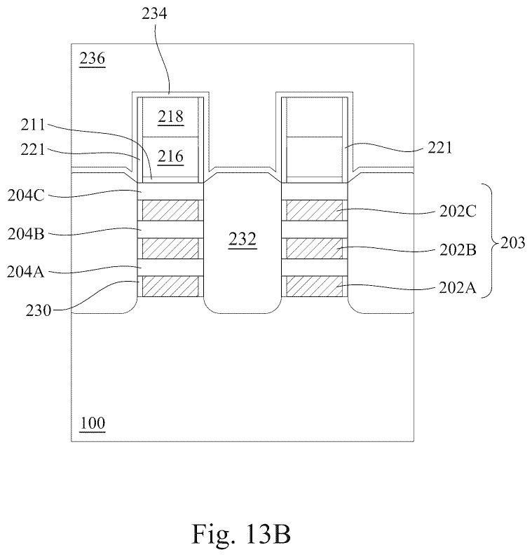

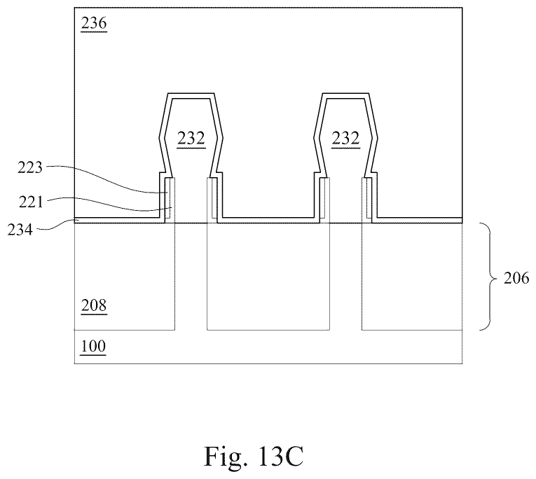

FIG. 4C illustrates a cross-sectional view formation of the STI regions 208, in accordance with some embodiments. In FIG. 4C, top surfaces of the STI regions 208 are non-planar. In other words, the top surfaces of the STI regions 208 are not at the same level. Interfaces between the STI regions 208 and the contact etch stop layers subsequently formed over the STI region 208 (see following FIG. 13C) may thus be non-planar, in accordance with some embodiments.

FIG. 4D illustrates a cross-sectional view formation of a dielectric layer 209 on the STI regions 208, in accordance with some embodiments. In some embodiments, a dielectric layer 209 can be formed over the STI regions 208. The dielectric layers on the STI regions 208 can be referred to as masks. In some embodiments, the dielectric layer 209 may include SiN, SiO₂, SiON, SiCN, SiCON, SiCO, high-k dielectric layer such as HfO, AlO or compositions of multiple layers.

The process described above with respect to FIGS. 2 through 4D is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIGS. 4A through 4D, appropriate wells (not separately illustrated) may be formed in the fin structures 206 and/or the nanostructures 203. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

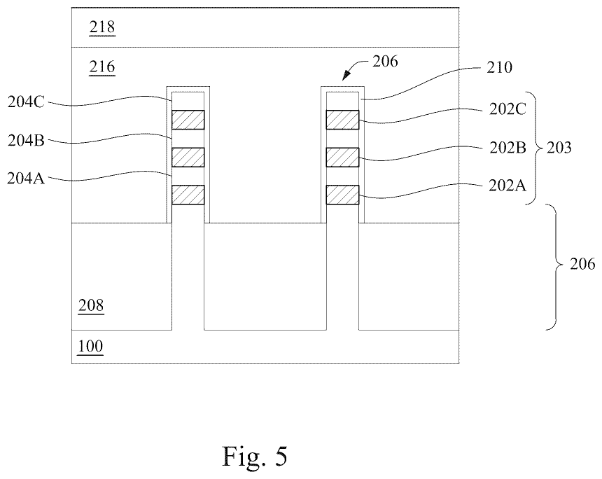

Reference is made to FIG. 5. FIG. 5 illustrates formation of a dummy gate structure, in accordance with some embodiments.

In FIG. 5, dummy dielectric layers 210 are formed on the fin structures 206 and/or the nanostructures 203 in the regions R1 and R2. The dummy dielectric layers 210 may be, for example, silicon oxide, silicon nitride, a combination thereof, or the like, and may be deposited or thermally grown according to acceptable techniques. A dummy gate layer 212 is formed over the dummy dielectric layers 210, and a mask layer 214 is formed over the dummy gate layer 212. The dummy gate layer 212 may be deposited over the dummy dielectric layers 210 and then planarized, such as by a CMP. The mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layer 214 may include, for example, silicon nitride, silicon oxynitride, or the like. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

Reference is made to FIGS. 6A through 6C. FIGS. 6A through 6C illustrate patterning the mask layer 214 and the dummy gate layer 212, in accordance with some embodiments. FIG. 6B illustrates a cross-sectional view along the cross-section 6B-6B in FIG. 6A. FIG. 6C illustrates a cross-sectional view along the cross-section 6C-6C in FIG. 6A.

In FIGS. 6A through 6C, the mask layer 214 (see FIG. 5) may be patterned using acceptable photolithography and etching techniques to form masks 218. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206.

Reference is made to FIGS. 7A and 7B. FIGS. 7A and 7B illustrate forming spacer layers, in accordance with some embodiments.

In FIGS. 7A and 7B, a first spacer layer 220 and a second spacer layer 222 are formed over the structures illustrated in FIGS. 6A and 6B, respectively. The first spacer layer 220 and the second spacer layer 222 will be subsequently patterned to act as spacers for forming self-aligned source/drain regions. In FIGS. 7A and 7B, the first spacer layer 220 is formed on top surfaces of the STI regions 208; top surfaces and sidewalls of the fin structures 206, the nanostructures 203, and the masks 218; and sidewalls of the dummy gates 216 and the dummy gate dielectric 211. The second spacer layer 222 is deposited over the first spacer layer 220. The first spacer layer 220 may be formed of silicon oxide, silicon nitride, silicon oxynitride, or the like, using techniques such as thermal oxidation or deposited by CVD, ALD, or the like. The second spacer layer 222 may be formed of a material having a different etch rate than the material of the first spacer layer 220, such as silicon oxide, silicon nitride, silicon oxynitride, or the like, and may be deposited by CVD, ALD, or the like.

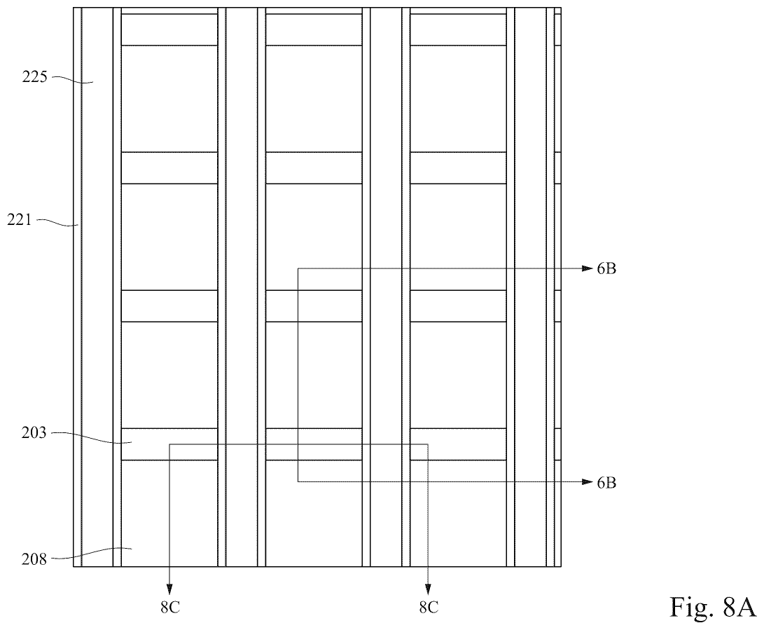

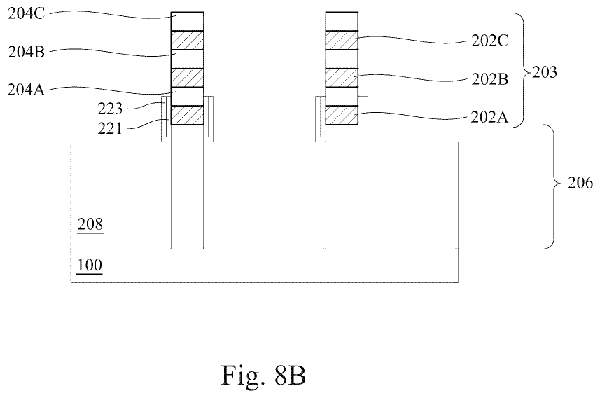

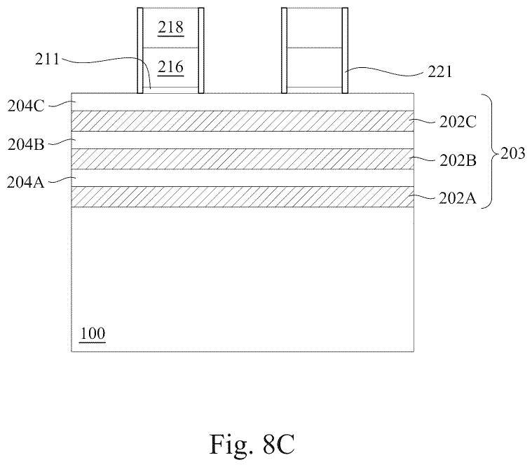

Reference is made to FIGS. 8A through 8C. FIGS. 8A through 8C illustrate formation gate spacers, in accordance with some embodiments. FIG. 8B illustrates a cross-sectional view along the cross-section 8B-8B in FIG. 8A. FIG. 8C illustrates a cross-sectional view along the cross-section 8C-8C in FIG. 8A.

In FIGS. 8A through 8B, the first spacer layer 220 and the second spacer layer 222 are etched to form first spacers 221 and second spacers 223. As will be discussed in greater detail below, the first spacers 221 and the second spacers 223 act to self-align subsequently formed source and drain regions (collectively referred to as source/drain regions), as well as to protect sidewalls of the fin structures 206 and/or nanostructures 203 during subsequent processing. The first spacer layer 220 and the second spacer layer 222 may be etched using a suitable etching process, such as an isotropic etching process (e.g., a wet etching process), an anisotropic etching process (e.g., a dry etching process), or the like. In some embodiments, the material of the second spacer layer 222 has a different etch rate than the material of the first spacer layer 220, such that the first spacer layer 220 may act as an etch stop layer when patterning the second spacer layer 222 and such that the second spacer layer 222 may act as a mask when patterning the first spacer layer 220. For example, the second spacer layer 222 may be etched using an anisotropic etch process wherein the first spacer layer 220 acts as an etch stop layer, wherein remaining portions of the second spacer layer 222 form second spacers 223 as illustrated in FIG. 8A. Thereafter, the second spacers 223 acts as a mask while etching exposed portions of the first spacer layer 220, thereby forming first spacers 221 as illustrated in FIG. 8A.

As illustrated in FIG. 8B, the first spacers 221 and the second spacers 223 are disposed on sidewalls of the fin structures 206 and/or nanostructures 203. In some embodiments, the spacers 221 and 223 only partially remain on sidewalls of the fin structures 206. In some embodiments, no spacer remains on sidewalls of the fin structures 206. As illustrated in FIG. 8B, in some embodiments, the second spacer layer 222 may be removed from over the first spacer layer 220 adjacent the masks 218, the dummy gates 216, and the dummy gate dielectrics 211, and the first spacers 221 are disposed on sidewalls of the masks 218, the dummy gates 216, and the dummy dielectric layers 211. In other embodiments, a portion of the second spacer layer 222 may remain over the first spacer layer 220 adjacent the masks 218, the dummy gates 216, and the dummy gate dielectrics 211.

In some embodiments, the first spacers 221 on gate sidewalls (also called gate spacers) have a small thickness (e.g., in a range from about 1 nm to about 10 nm) so as to reduce gate-to-gate pitch without significant reduction in source/drain region size. In some embodiments, the first spacers 221 on gate sidewalls is formed of as low-dielectric constant (low-k) materials (e.g., porous silicon oxide) having a k-value, for example, less than about 3.5. The low-k material can aid in reducing parasitic capacitance between, for example, the subsequently formed metal gates and source/drain contacts.

The above disclosure generally describes a process of forming spacers. Other processes and sequences may be used. For example, fewer or additional spacers may be utilized, different sequence of steps may be utilized (e.g., the first spacers 221 may be patterned prior to depositing the second spacer layer 222), additional spacers may be formed and removed, and/or the like.

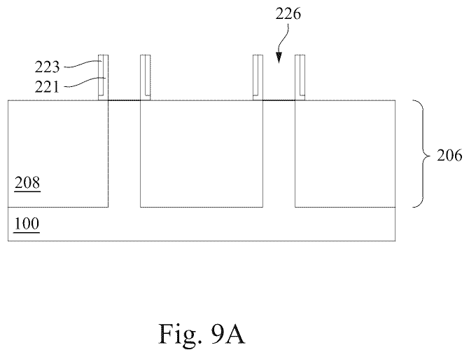

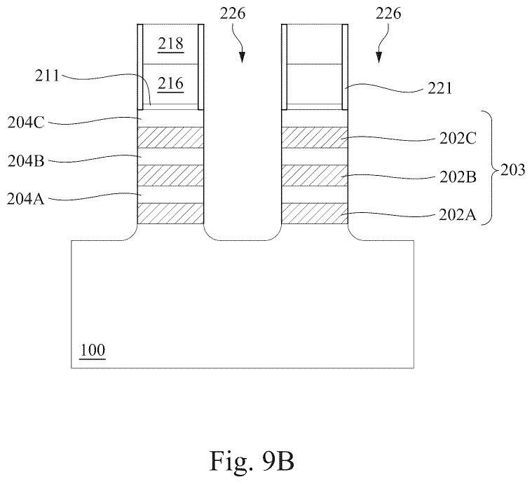

Reference is made to FIGS. 9A and 9B. FIGS. 9A and 9B illustrates forming source/drain recesses 226, in accordance with some embodiments.

In FIGS. 9A and 9B, source/drain recesses 226 are formed in the fin structures 206, the nanostructures 203, and the substrate 100, in accordance with some embodiments. Epitaxial source/drain regions will be subsequently formed in the source/drain recesses 226. The source/drain recesses 226 may extend through the first nanostructures 202 and the second nanostructures 204, and into the substrate 100. As illustrated in FIG. 9A, bottom surfaces of the source/drain recesses 226 may be level with top surfaces of the STI regions 208, as an example. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The first spacers 221, the second spacers 223, and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

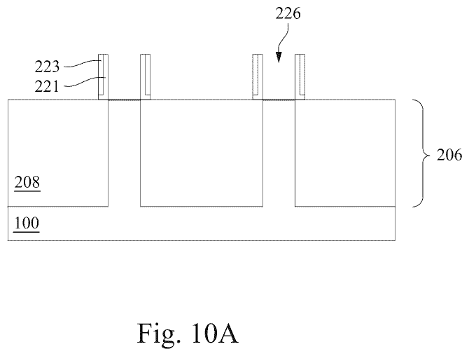

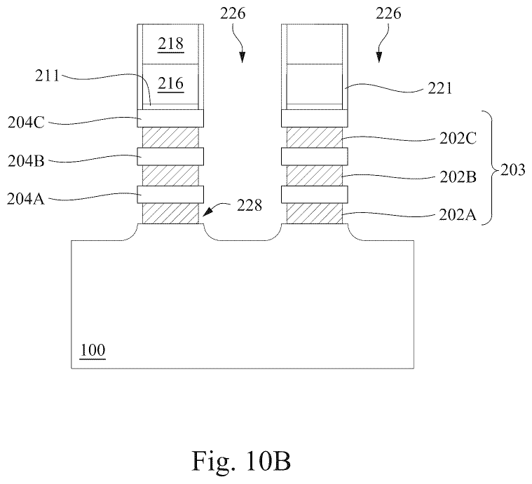

Reference is made to FIGS. 10A and 10B. FIGS. 10A and 10B illustrate laterally recessing the nanostructure of the nanostructures 204, in accordance with some embodiments.

In FIGS. 10A and 10B, portions of sidewalls of the layers of the multi-layer stack 203 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in recesses 228 are illustrated as being straight in FIG. 10B, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

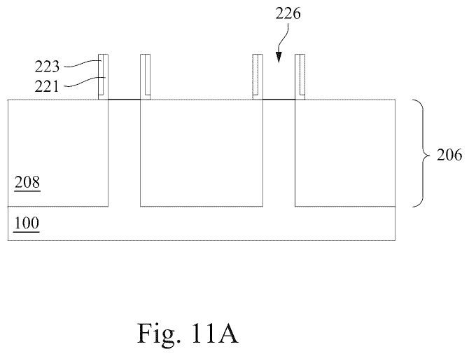

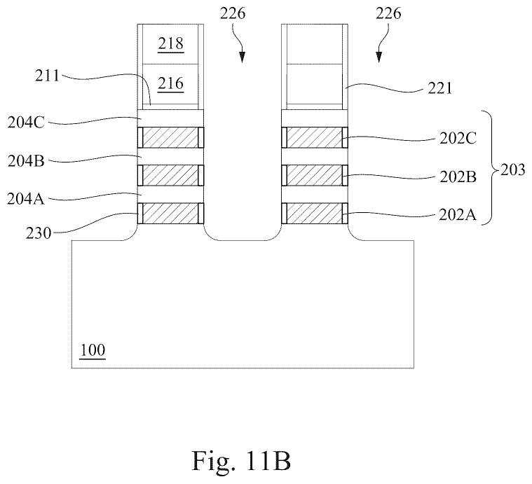

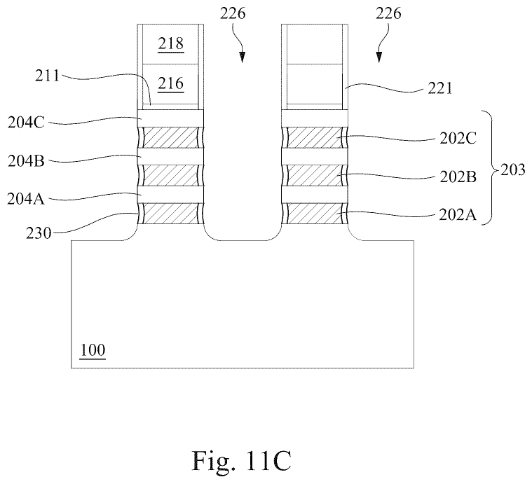

Reference is made to FIGS. 11A and 11B. FIGS. 11A and 11B illustrates forming inner spacers 230, in accordance with some embodiments.

In FIGS. 11A and 11B, inner spacers 230 are formed in the sidewall recess 228. The inner spacers 230 may be formed by depositing an inner spacer layer (not separately illustrated) over the structures illustrated in FIGS. 10A and 10B. The inner spacers 230 act as isolation features between subsequently formed source/drain regions and gate structure. As will be discussed in greater detail below, source/drain regions will be formed in the recesses 226, and the first nanostructures 202 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

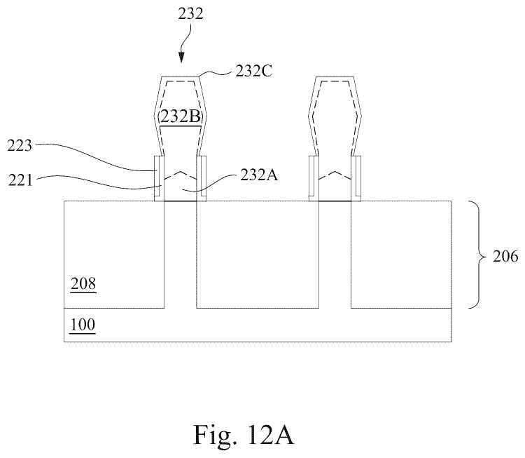

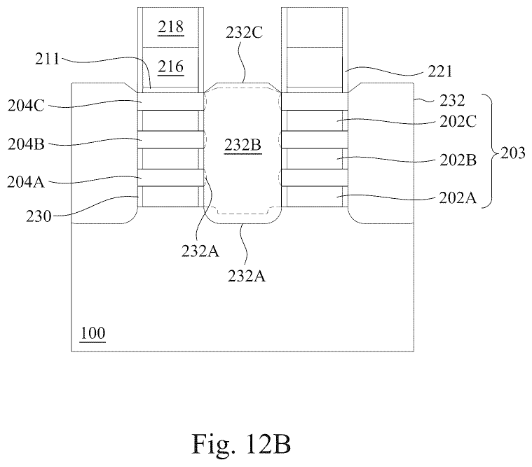

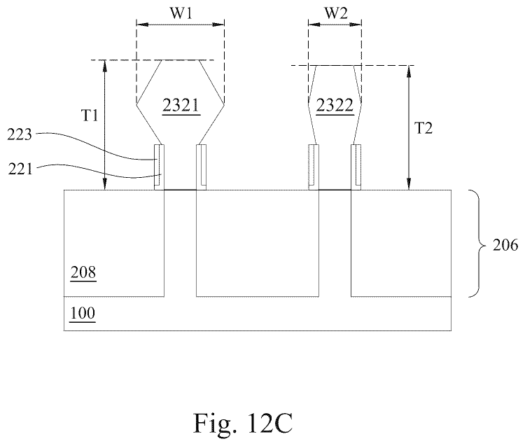

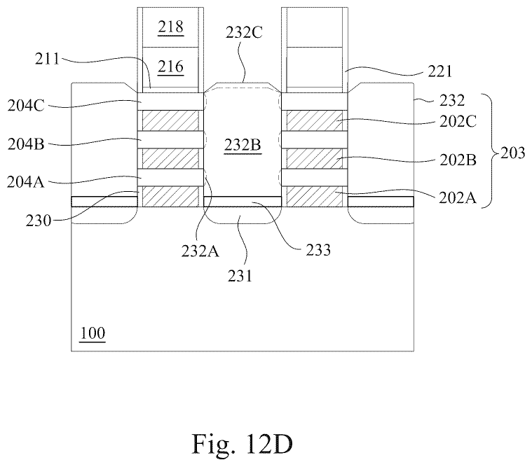

Moreover, although the outer sidewalls of the inner spacers 230 are illustrated as being straight in FIG. 11B, the outer sidewalls of the inner spacers 230 may be concave or convex. As an example, FIG. 11C illustrates an embodiment in which sidewalls of the first nanostructures 202 are concave, outer sidewalls of the inner spacers 230 are concave, and the inner spacers are recessed from sidewalls of the second nanostructures 204. The inner spacer layer may be etched by an anisotropic etching process, such as RIE, NBE, or the like. The inner spacers 230 may be used to prevent damage to subsequently formed source/drain regions (such as the epitaxial source/drain regions 232, discussed below with respect to FIGS. 12A-12D) by subsequent etching processes, such as etching processes used to form gate structures.

Reference is made to FIGS. 12A through 12D. FIGS. 12A through 12D illustrate formation of source/drain epitaxial source/drain regions 232, in accordance with some embodiments.

FIG. 12A illustrates reference cross-section C-C′ illustrated in FIG. 1 that extends through source/drain regions along the longitudinal direction of the gate region. FIG. 12B illustrates a cross-sectional view of reference cross-section B-B′ illustrated in FIG. 1 that extends through a fin along a longitudinal axis of the fin. In FIGS. 12A and 12B, epitaxial source/drain regions 232 are formed in the source/drain recesses 226.

In some embodiments, the source/drain regions 232 may exert stress on the second nanostructures 204, thereby improving device performance. As illustrated in FIG. 12B, the epitaxial source/drain regions 232 are formed in the source/drain recesses 226 such that each dummy gate 216 is disposed between respective neighboring pairs of the epitaxial source/drain regions 232. In some embodiments, the first spacers 221 are used to separate the epitaxial source/drain regions 232 from the dummy gates 212, and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The source/drain regions may have an impurity concentration of between about 1×10¹⁷ atoms/cm³ and about 1×10²² atoms/cm³. The n-type and/or p-type impurities for source/drain regions may be any of the impurities previously discussed. In some embodiments, the epitaxial source/drain regions 232 may be in situ doped during growth.

As a result of the epitaxy processes used to form the epitaxial source/drain regions 232, upper surfaces of the epitaxial source/drain regions 232 have facets which expand laterally outward beyond sidewalls of the nanostructures 203. As illustrated in FIG. 12A, adjacent epitaxial source/drain regions 232 remain separated after the epitaxy process is completed. In some embodiments, facets of the upper surfaces of the epitaxial source/drain regions 232 cause adjacent epitaxial source/drain regions 232 to merge. In FIG. 12A, the first spacers 221, 223 may be formed to a top surface of the STI regions 208 thereby blocking the lateral epitaxial growth. In some embodiments, the spacer etch used to form the first spacers 221, 223 may be adjusted to remove the spacer material to allow the epitaxially grown region to extend to the surface of the STI region 208.

In one or more embodiments of the present disclosure, the epitaxial source/drain regions 232 may include one or more semiconductor material layers. For example, the epitaxial source/drain regions 232 may include a first semiconductor material layer 232A, a second semiconductor material layer 232B, and a third semiconductor material layer 232C, which are distinguished in FIG. 12B by using dash-lines. Any number of semiconductor material layers may be used for the epitaxial source/drain regions 232. Each of the first semiconductor material layer 232A, the second semiconductor material layer 232B, and the third semiconductor material layer 232C may be formed of different semiconductor materials and may be doped to different dopant concentrations. In embodiments in which the epitaxial source/drain regions 232 include three semiconductor material layers, the first semiconductor material layer 232A may be deposited over surfaces of the nanostructures 204 and the substrate 100 exposed from the source/drain recesses 226, the second semiconductor material layer 232B may be deposited over the first semiconductor material layer 232A, and the third semiconductor material layer 232C may be deposited over the second semiconductor material layer 232B.

In some embodiments, the epitaxial source/drain regions 232 may be formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes. The epitaxial source/drain regions 232, the nanostructures 202, 204, and/or the fin structure 206 may be implanted with impurities, similar to the process previously described for forming LDD regions, followed by an anneal. In some embodiments, the epitaxial source/drain regions 232 are in-situ doped or undoped during the epi process. When the epitaxial source/drain regions 232 are undoped, they may be doped in a subsequent process. The doping may be achieved by an ion implantation process, plasma immersion ion implantation (PIII) process, gas and/or solid source diffusion process, or other suitable process. Afterwards, the epitaxial source/drain regions 232 may be exposed further to annealing processes, such as a rapid thermal annealing process.

In some embodiments, as illustrated in FIG. 12B, the source/drain regions 232 have portions embedded in the substrate 100.

FIG. 12C illustrates formation of source/drain regions 232 including a first source/drain region 2321 and a second source/drain region 2322, in accordance with some embodiments. FIG. 12C illustrates reference cross-section C-C′ illustrated in FIG. 1 that extends through source/drain regions along the longitudinal direction of the gate region.

In FIG. 12C, the first source/drain region 2321 has a thickness T1 from a top surface of the fin structure 206 to a top surface of the first source/drain region 2321. The first source/drain region 2321 has a width W1. The second source/drain region 2321 has a thickness T2 from a top surface of the fin structure 206 to a top surface of the second source/drain region 2321. The second source/drain region 2322 has a width W2. In some embodiments, the thickness T1 is different from the thickness T2. In some embodiments, the width W1 is different from the width W2. As illustrated in FIG. 12C, in some embodiments, the source/drain regions 2321 overhangs the STI regions 208.

FIG. 12D illustrates formation of source/drain regions 232, in accordance with some embodiments. FIG. 12D illustrates a cross-sectional view of reference cross-section B-B′ illustrated in FIG. 1 that extends through a fin along a longitudinal axis of the fin.

As illustrated in FIG. 12D, in some embodiments, before forming the first semiconductor layers 232A of the source/drain regions 232, un-doped semiconductor layers 231 are formed in the source/drain recesses 226. For example, material of the un-doped semiconductor layers 231 can include un-doped silicon. In some embodiments, material of the un-doped semiconductor layers 231 can include material different from the substrate 100. For example, the material of the un-doped semiconductor layers 231 may include un-doped SiGe. In some embodiments, the un-doped semiconductor layers 231 are epitaxially grown. In FIG. 5, top surfaces of the un-doped semiconductor layers 231 have elevations level with bottom surfaces of the bottommost inner spacers 230. In some embodiments, the top surfaces of the un-doped semiconductor layers 231 are lower than the bottommost nanostructures 204A.

In some embodiments, before forming the first semiconductor layers 232A of the source/drain regions 232, a plurality of dielectric layers 233 may be formed in the source/drain recesses 226. The dielectric layer 233 can be interchangeably referred to a dielectric barrier layer or a leakage barrier for reducing leakage current. In some embodiments, the dielectric layer 233 can be made of a different material than the inner spacer 230. In some embodiments, the dielectric layer 233 can be formed during a same process as forming the inner spacer 230, in which the material to form the inner spacer 230 can be remained at the bottom of the source/drain recesses 226 to act as the dielectric layer 233. In some embodiments, the dielectric layer 233 is made of an oxide-containing material (e.g., SiO₂), a nitrogen-containing material (e.g., SiON, SiN, Si₃N₄), a carbon-containing material (e.g., SiOC, SIOCN), a high-k dielectric layer (e.g., HfO, AlO), the like, or combinations thereof. In some embodiments, the dielectric layer 233 may be made of a material having a dielectric constant greater than about 7.9 (e.g., high dielectric constant (high-k) material). For example, the dielectric layer 233 may be made of a high dielectric constant (high-k) material, such be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. In FIG. 12D, the dielectric layers 233 are between the un-doped semiconductor layers 231 and the second semiconductor layers 232B of the source/drain regions 232. In some embodiments, the top surfaces of the dielectric layers 233 are lower than the bottommost nanostructures 204A.

Reference is made to FIGS. 13A through 13C. FIGS. 13A through 13C illustrate forming an interlayer dielectric (ILD) layer 236 and a contact etch stop layer (CESL) 234, in accordance with some embodiments.

In FIGS. 13A-13C, an interlayer dielectric (ILD) layer 236 is deposited over the structure illustrated in FIGS. 12A and 12B. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 236 and the epitaxial source/drain regions 232, the masks 214, and the first spacers 221. The CESL 234 may comprise a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 236.

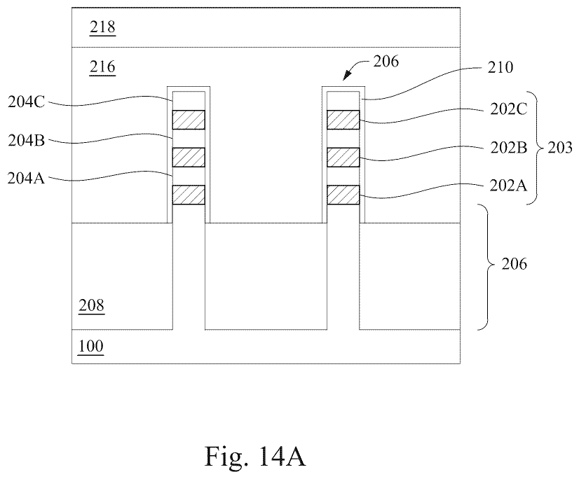

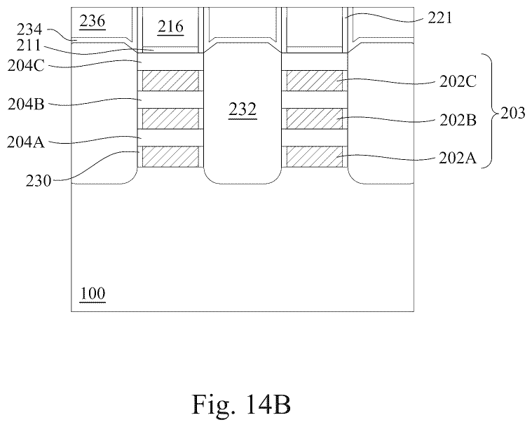

Reference is made to FIGS. 14A and 14B. FIGS. 14A and 14B illustrate performing a planarization process on the structure as illustrated in FIGS. 13A through 13C, in accordance with some embodiments.

In FIGS. 14A and 14B, a planarization process, such as a CMP, may be performed to level the top surface of the ILD layer 236 with the top surfaces of the dummy gates 216 or the masks 218. The planarization process may also remove the masks 218 on the dummy gates 216, and portions of the first spacers 221 along sidewalls of the masks 218. After the planarization process, top surfaces of the dummy gates 216, the first spacers 221, and the ILD layer 236 are level within process variations. Accordingly, the top surfaces of the dummy gates 212 are exposed through the ILD layer 236. In some embodiments, the masks 218 may remain, in which case the planarization process levels the top surface of the ILD layer 236 with top surface of the masks 218 and the first spacers 221.

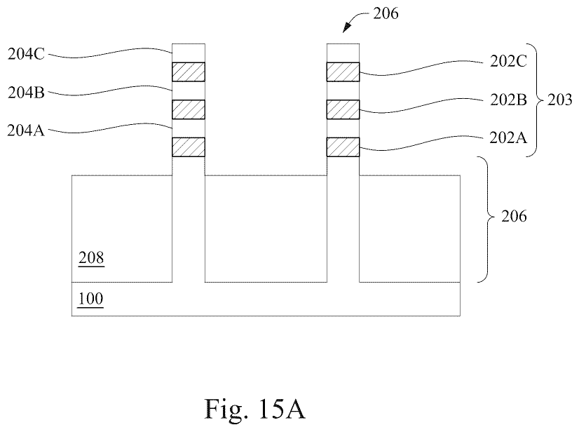

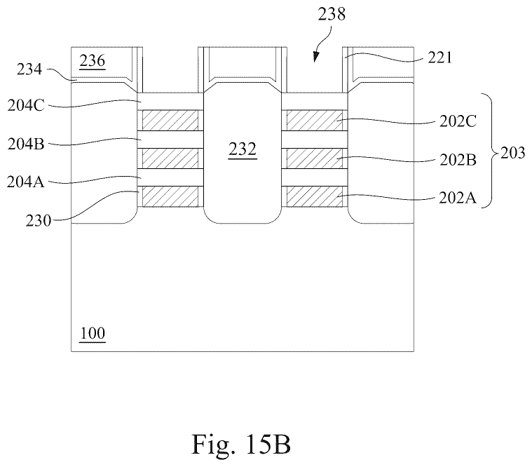

Reference is made to FIGS. 15A and 15B. FIGS. 15A and 15B illustrate removal of dummy gate structures, in accordance with some embodiments.

In FIGS. 15A and 15B, the dummy gates 216, and the masks 218 if present, are removed in one or more etching steps, so that gate trenches 238 are formed between corresponding gate spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the protective layer 237 or the first spacers 221. Each gate trench 238 exposes and/or overlies portions of nanostructures 204, which will serve as channel regions in subsequently completed GAA-FETs. The nanostructures 204 serving as the channel regions are disposed between neighboring pairs of the epitaxial source/drain regions 232. During the removal, the dummy dielectric layers 211 may be used as etch stop layers when the dummy gates 216 are etched. The dummy dielectric layers 211 may then be removed after the removal of the dummy gates 216.

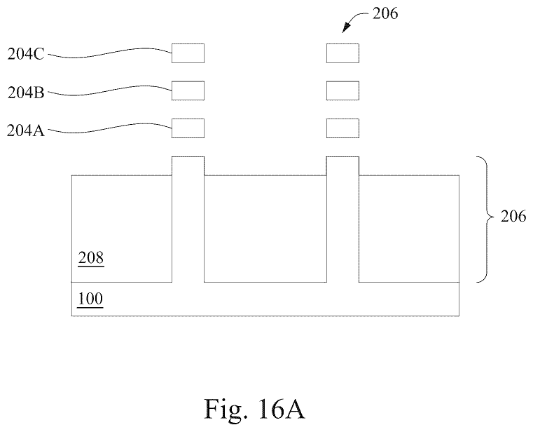

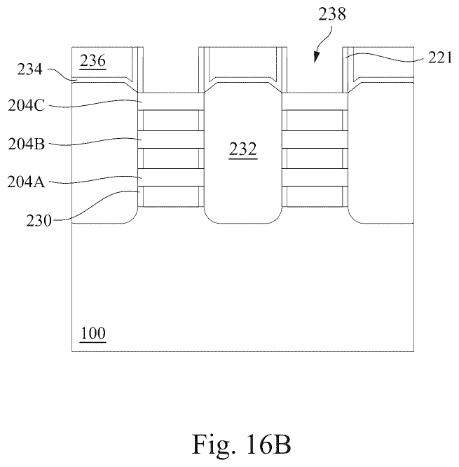

Reference is made to FIGS. 16A and 16B. FIGS. 16A and 16B illustrate removal of the nanostructures 202, in accordance with some embodiments.

In FIGS. 16A and 16B, the first nanostructures 202 in the gate trenches are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIGS. 10A-10B) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

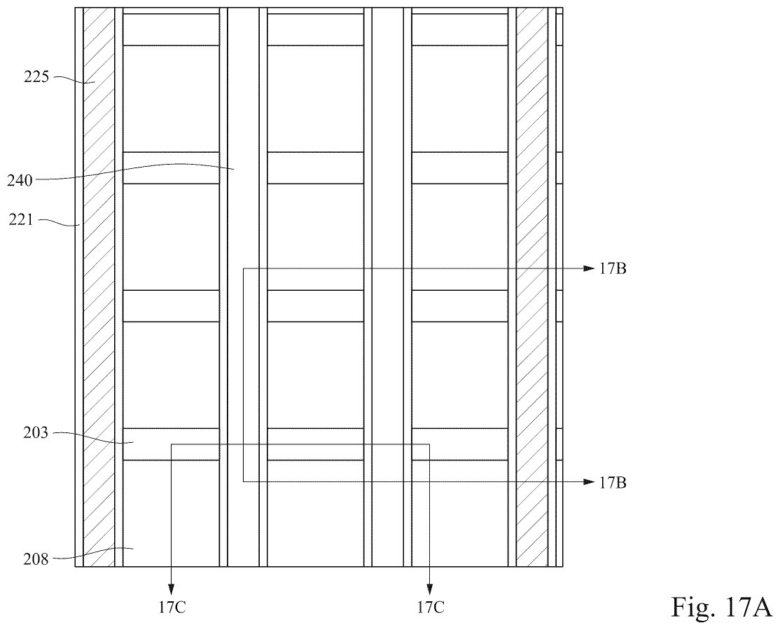

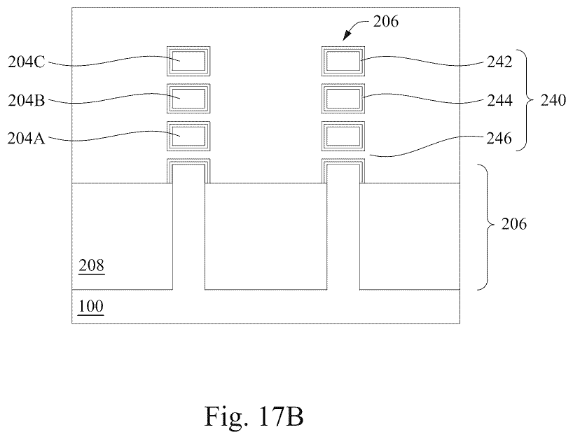

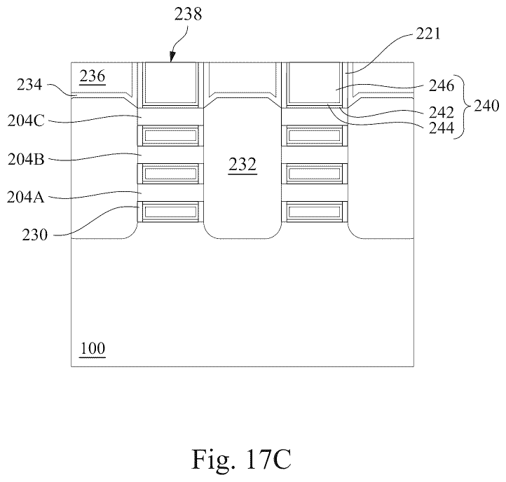

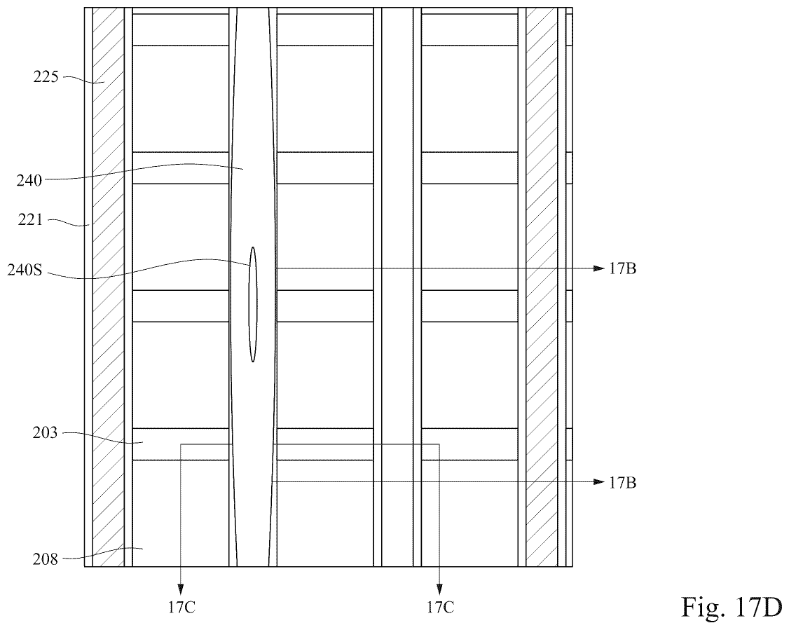

Reference is made to FIGS. 17A through 17C. FIGS. 17A through 17C illustrate formation of replacement gate structures 240, in accordance with some embodiments. FIG. 17B illustrates a cross-sectional view along the cross-section 17B-17B in FIG. 17A. FIG. 17C illustrates a cross-sectional view along the cross-section 17C-17C in FIG. 17A.

In FIGS. 17A through 17C, replacement gate structures 240 are respectively formed in the gate trenches 238 to surround each of the nanosheets 204 suspended in the gate trenches 238. The gate structures 240 may be final gates of GAA FETs. The final gate structure may be a high-k/metal gate stack, however other compositions are possible. In some embodiments, each of the gate structures 240 forms the gate associated with the multi-channels provided by the plurality of nanosheets 204. For example, high-k/metal gate structures 240 are formed within the sheet-to-sheet spaces provided by the release of nanosheets 204. In various embodiments, the high-k/metal gate structure 240 includes an interfacial layer 242 formed around the nanosheets 204, a high-k gate dielectric layer 244 formed around the interfacial layer 242, and a gate metal layer 246 formed around the high-k gate dielectric layer 244 and filling a remainder of gate trenches 238. Formation of the high-k/metal gate structures 240 may include one or more deposition processes to form various gate materials, followed by a CMP process to remove excessive gate materials, resulting in the high-k/metal gate structures 240 having top surfaces level with a top surface of the protective layer 237. As illustrated in the cross-sectional view of FIG. 17A, the high-k/metal gate structure 240 surrounds each of the nanosheets 204, and thus is referred to as a gate of a GAA FET. In some embodiments, a thickness of one of the gate spacer 221 is greater than a thickness of the gate dielectric 244 of the gate structure 240.

In some embodiments, as illustrated in FIG. 17B, the topmost surfaces of the STI regions 208 intermix at an interface between the gate structure 240 and the STI regions 208. In some embodiments, since the top surfaces of the STI regions 208 have different heights (see FIG. 4C), bottommost surfaces of one of the gate structure 240 are not at the same depths. In some embodiments, the topmost surface of one of the gate structures 240 may thus be not planar.

In some embodiments, the interfacial layer 242 is silicon oxide formed on exposed surfaces of semiconductor materials in the gate trenches 238 by using, for example, thermal oxidation, chemical oxidation, wet oxidation or the like. As a result, surface portions of the nanosheets 204 exposed in the gate trenches 238 are oxidized into silicon oxide to form interfacial layer 242.

In some embodiments, the high-k gate dielectric layer 244 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 246 includes one or more metal layers. For example, the gate metal layer 246 may include one or more work function metal layers stacked one over another and a fill metal filling up a remainder of gate trenches 238. The one or more work function metal layers in the gate metal layer 246 provide a suitable work function for the high-k/metal gate structures 240. For an n-type GAA FET, the gate metal layer 246 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the gate metal layer 246 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, as illustrated in FIG. 17A, dielectric-based gates 225 can be formed to replace with some dummy gate structures formed of the dummy gate dielectrics 211, the dummy gates 216 and the mask 218 before forming the gate structures 240. In some embodiments, dielectric-based gates 225 can be formed to replace with some gate structures 240 after forming the gate structures 240. Formation of the dielectric-based gates 22 may include, for example, etching the dummy gate dielectrics 211, the dummy gates 216, the mask 218, the nanostructures 203 to form isolation trenches along the lengthwise direction of the gate structures 240, followed by forming dielectric material in the isolation trenches. The dielectric-based gates 225 are common to implement channel layer cuts (or in the oxide definition (OD)) at the end of the nanostructures 203. The dielectric-based gates 225 may referred to as continuous polysilicon on oxide diffusion (OD) edges (CPODEs). In some embodiments, the dielectric-based gate 225 can be made of silicon oxide (SiOₓ), silicon nitride (SiₓN_{y}), silicon oxynitride (SiON), dielectric material(s), other suitable material, or a combination thereof.

FIG. 17D illustrates a top view of forming the gate structures 240, in accordance with some embodiments. In some embodiments, the outermost surface of a gate electrode 240 along the gate direction is non-linear. In other words, an interface between gate spacer 221 and one of the gate structures 240 is curved In some embodiments, one of the gate structures 240 has a seam 240S.

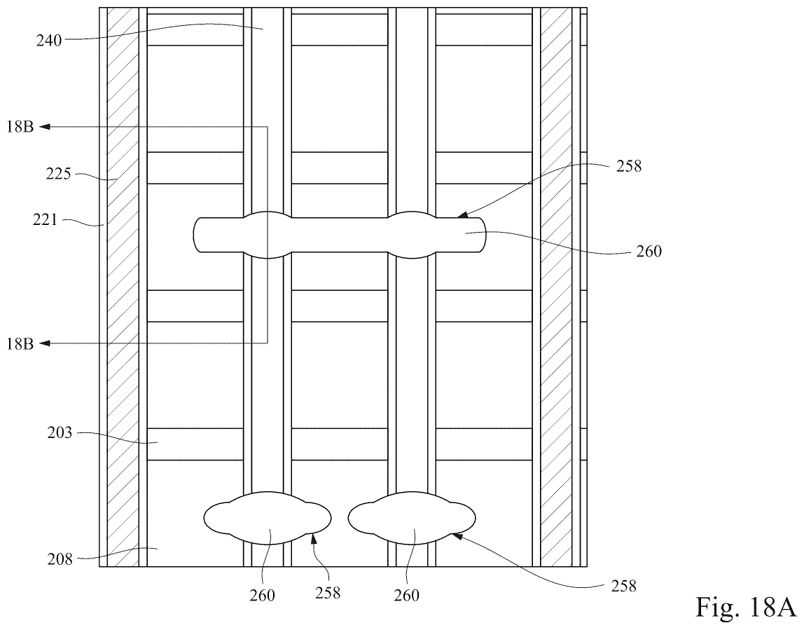

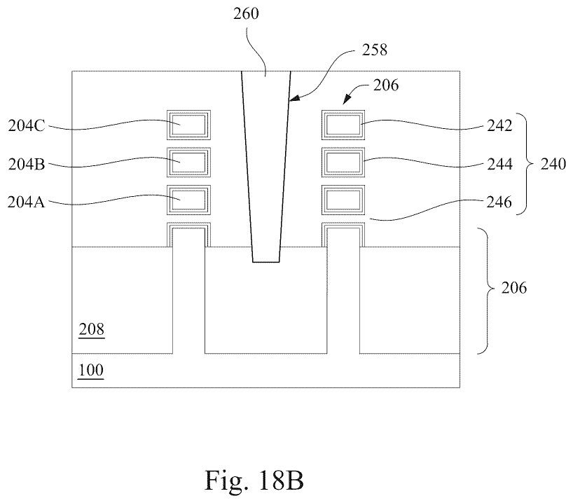

Reference is made to FIGS. 18A and 18B. FIGS. 18A and 18B illustrate formation of gate isolation structures 260, in accordance with some embodiments. FIG. 18B illustrates a cross-sectional view along the cross-section 18B-18B in FIG. 18A.

Formation of the gate isolation structures 260 may include an etching step can break a continuous gate structure 240 into separate gate structures with no or negligible impact on underlying materials. Such etching step can be referred to as a “gate cut” or “cut metal gate” step. In some embodiments, a patterned mask (e.g., patterned photoresist) is first formed over the substrate 100, except for CMG target regions, and then one or more etching processes are performed on the exposed CMG target regions to form gate cut openings 258 each breaking a continuous gate structure 240 into separate gate structures 240. Afterwards, gate isolation structures 260 are formed in the gate cut openings 258, so as to electrically isolate the separate gate structures 240. Formation of the isolation structures 260 includes, for example, depositing one or more dielectric material overfilling the gate cut openings 258, followed by performing a planarization step (e.g., CMP) to remove excess dielectric material outside the gate cut openings 258. The isolation structures 260 may be formed to replace the gate structures 240 between the adjacent ILD layers 236 (see FIG. 17C).

In some embodiments, the gate isolation structures 260 may be made of a metal oxide material. In some embodiments, the gate isolation structures 260 may be made of a material having a dielectric constant greater than about 9 (e.g., high dielectric constant (high-k) material). For example, the gate isolation structures 260 may be made of a high dielectric constant (high-k) material, such as hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The gate isolation structures 260 may be formed of a homogenous material, or may have a composite structure including more than one layer. In some embodiments, the gate isolation structures 260 may include dielectric liners, which may be formed of, for example, silicon oxide. In some embodiments, the gate isolation structures 260 may include at least two layers such as liner and dielectric bulk fill.

As illustrated in FIG. 18A, in some embodiments, the gate isolation structures 260 may include separated isolation portions. In some embodiments, an interface between one of the gate isolation structures 260 and the gate structure 240 are curved. In other words, the interface between one of the gate isolation structures 260 and the gate structure 240 can be non-linear. In some embodiments, the gate isolation structures 260 may be in contact with the gate spacers 221. In some embodiments, end portions of the gate isolation structures 260 have curved or non-linear profiles.

In FIG. 18B, in some embodiments, gate isolation structures 260 extend into the STI regions 208. In some embodiments, a bottommost portion of the gate isolation structures 260 is lower than bottommost portion of gate structure 240. In some embodiment, as shown in FIG. 18B, at least a portion of gate isolation structures 260 extends into the STI regions 208. In some embodiments, at least a portion of gate isolation structures 260 is over and overhangs the STI regions 208.

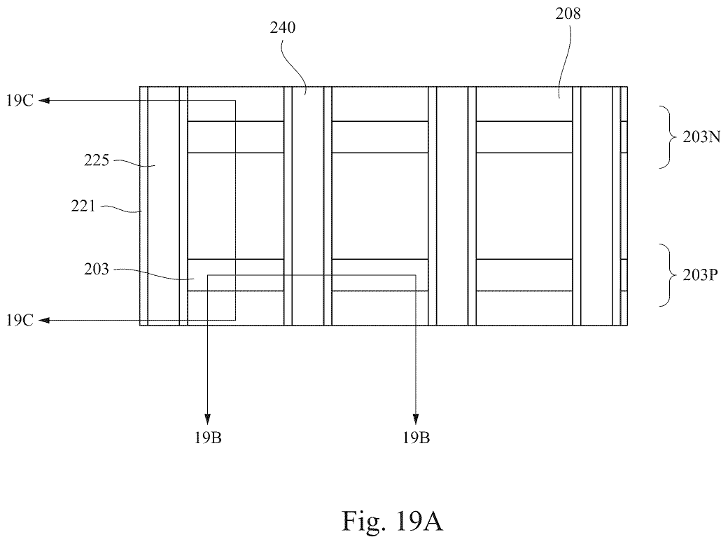

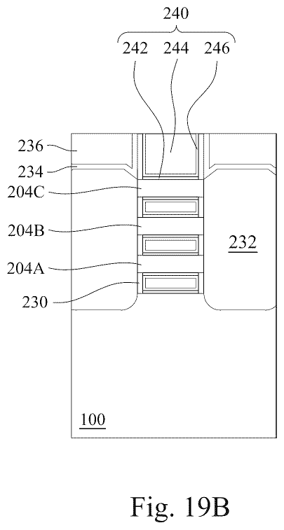

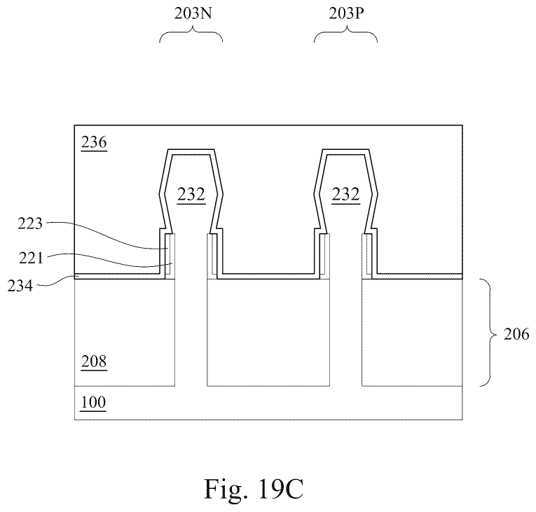

After the dielectric-based gate 225 and the gate isolation structures 260 are formed, the nanostructures 203 and the gate structures 240 are cut and a cell can be defined. Reference is made to FIGS. 19A through 19C. FIG. 19A illustrates a top view of a simplified diagram of the structure as illustrated in FIG. 18A. FIG. 19B illustrates a cross-sectional view along the cross-section 19B-19B in FIG. 19A. FIG. 19C illustrates a cross-sectional view along the cross-section 19C-19C in FIG. 19A.

In one or more embodiments, the structure as illustrated in FIGS. 19A through 19C may include active regions 203N and 203P with different conductive types. In some embodiments, the region 203N includes a p-type well region in the substrate 100, and the source/drain regions 232 on the p-type well region in the region 203N have n-type dopant. In some embodiments, the region 203P includes an n-type well region in the substrate, and the source/drain regions 232 on the n-type well region in the region 203P have p-type dopant.

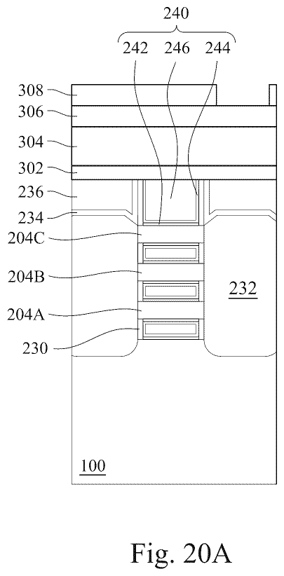

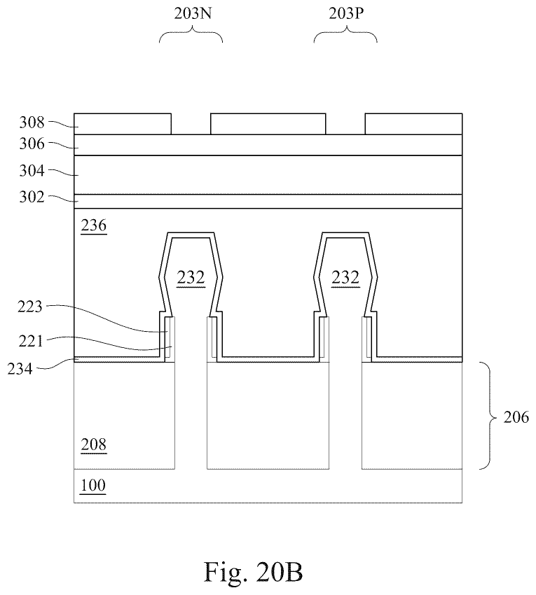

Reference is made to FIGS. 20A through 23B to illustrate formation of source/drain contacts 270. FIGS. 20A, 21A, 22A and 23A illustrate reference cross-section 19B-19B illustrated in FIG. 19A. FIGS. 20B, 21B, 22B and 23B illustrate reference cross-section 19C-19C illustrated in FIG. 19A.

In FIGS. 20A and 20B, a contact etch stop layer (CESL) 302 is formed over the ILD layer 236 and the gate structures 240. The CESL 302 may be formed of a dielectric material, such as silicon nitride, silicon oxide, silicon oxynitride, or the like. The CESL 302 may be formed by any suitable method, such as CVD, ALD, or the like. An inter-layer dielectric (ILD) layer 304 can be deposited over the CESL 302. The ILD layer 304 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. The CESL 302 may have a high etching selectivity from the etching of the ILD layer 304. In some embodiments, a thickness of the CESL 302 is less than a thickness of the ILD layer 304. A hard mask layer 306 is formed over the CESL 302. A photoresist layer 308 with patterns is formed over the hard mask layer 306.

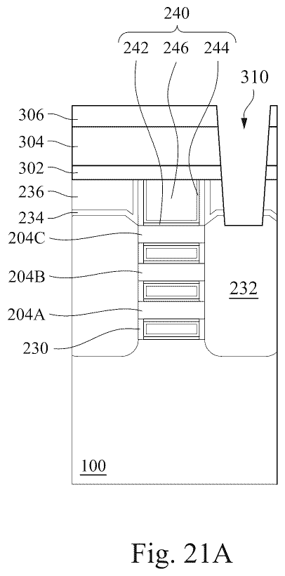

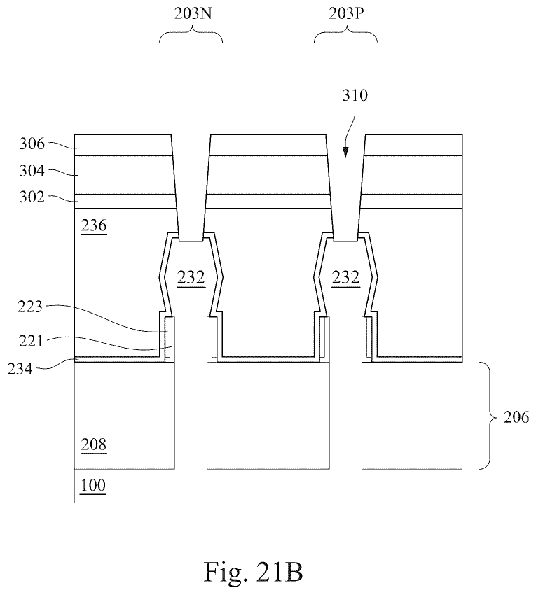

Openings 310 are formed using acceptable photolithography and etching techniques. As illustrated in FIGS. 21A and 21B, the hard mask layer 306 is patterned using the patterns of the photoresist layer 308, followed by removal of the photoresist layer 308. The ILD layer 304 and the CESL 302 are then etched based on the patterned mask layer 306 to form the openings 310 over the source/drain regions 232. In FIGS. 21A and 21B, the openings 310 extend through the ILD layer 236 and the CESL 234 to the source/drain regions 232. In some embodiments, as illustrated in FIGS. 21A and 21B, the openings 310 extend into the source/drain regions 232.

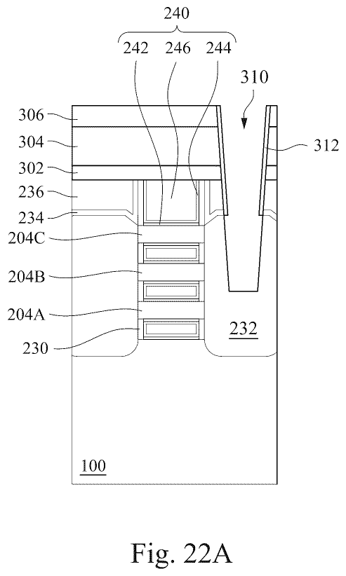

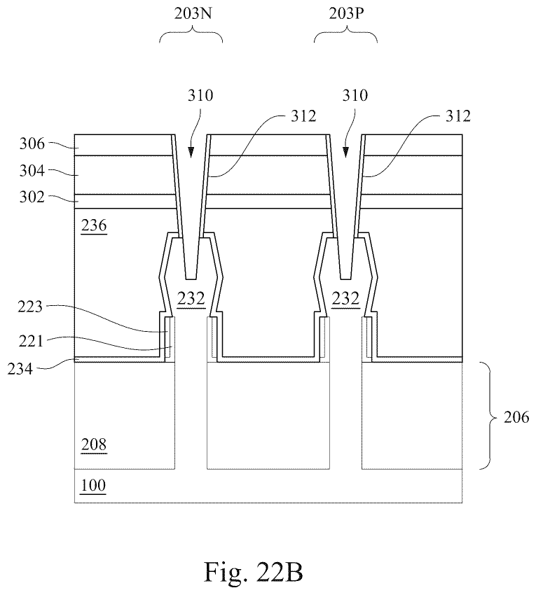

Reference is made to FIGS. 22A and 22B. Barrier interface layers 312 are deposited in the openings 310. In some embodiments, the barrier interface layers 312 include dielectric material such as silicon nitride for avoiding current leakage. In some embodiments, the barrier interface layers 312 may include SiON, SiCN, SiCON, SiCO, high-k dielectric such as HfO, AlO, or composition of multiple layers. The barrier interface layers 312 are then etched through to expose the source/drain regions 232. In one or more embodiments, the openings 310 are deepened after etching through the barrier interface layers 312.

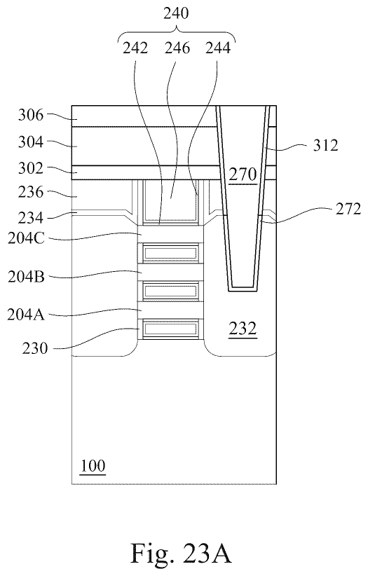

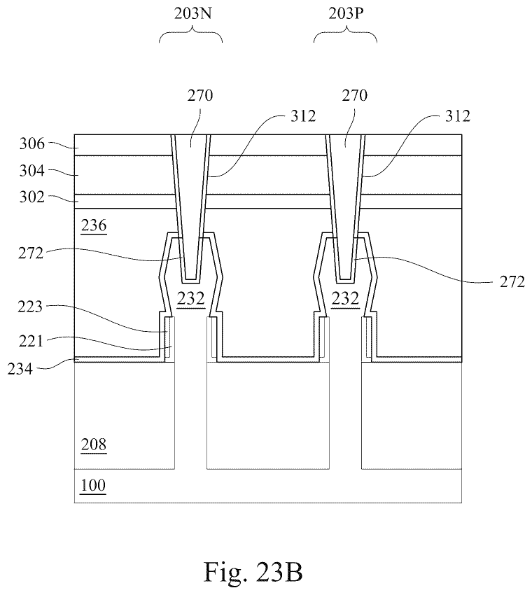

In FIGS. 23A and 23B, a metal silicidation process is performed on the source/drain regions 232 to form silicide regions 272. The silicide regions 272 have curved profiles in the cross-sectional view of FIG. 23B. The metal silicidation process is to make a reaction between metal and silicon (or polycrystalline silicon). In some embodiments, a metal layer is formed on the source/drain region 272. Subsequently, regarding the metal silicidation process, a first rapid thermal annealing (RTA) process may be performed in, for example, Ar, He, N₂ or other inert atmosphere at a first temperature, such as lower than 200~300 ° C., to convert the deposited metal layer into metal silicide. This is followed by an etching process to remove the unreacted metal layer. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400~500 ° C., thereby forming a silicide region 272 with low resistance. In some embodiments, the silicide region 272 may include titanium silicide (TiSi), TiSi₂, nickel silicide (NiSi), PtSi, MoSi, MOSi₂, cobalt silicide (CoSi), CoSi₂, Ni—Pt, or combinations thereof.

Source/drain contacts 270 (also called metal on diffusion (MD)) formed subsequently are formed in the ILD layers 236, 304 and the CESL 234, 302. Formation of the source/drain contacts 270 includes, by way of example and not limitation, performing one or more etching processes to form contact openings extending though the ILD layer 236 and the CESL 234 to expose the source/drain epitaxy regions 232, depositing one or more metal materials (e.g., W, Ru, Co, Cu, Ti, TiN, Ta, TaN, Mo, Ni, the like or combinations thereof) overfilling the contact openings 310, and then performing a CMP process to remove excessive metal materials outside the contact openings 310. As illustrated in FIGS. 23A and 23B, the source/drain contacts 270 have inverted trapezoidal cross-section, and a lateral distance from the source/drain contact 270 to the gate spacer 221 increases from top of the source/drain contact 270 to bottom of the source/drain contact 270.

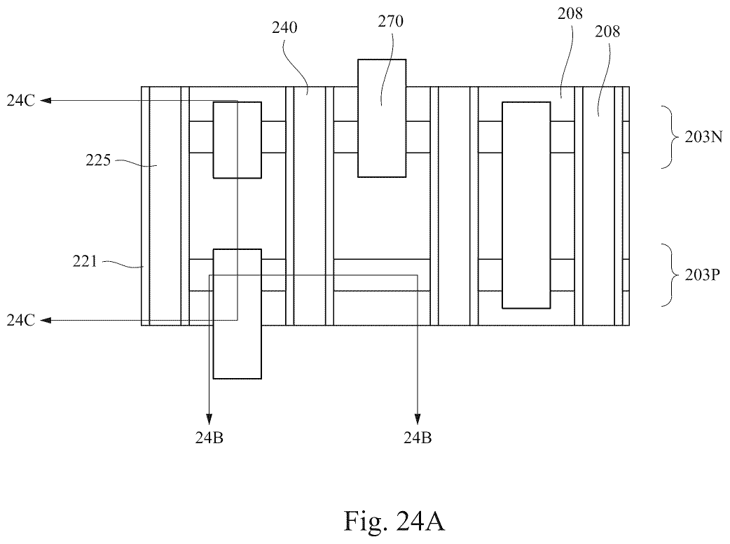

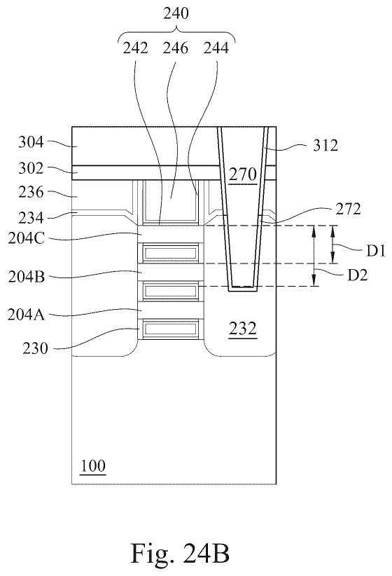

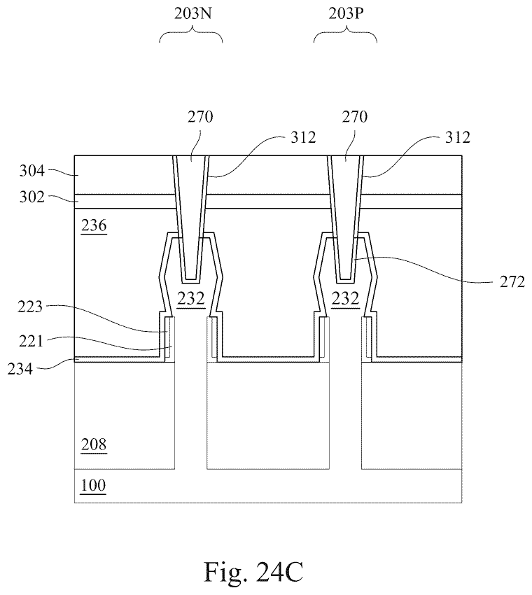

Reference is made to FIGS. 24A through 24C. FIG. 24A illustrates a top view of forming the source/drain contacts 270. FIG. 24B illustrates a cross-sectional view along the cross-section 24B-24B in FIG. 24A. FIG. 24C illustrates a cross-sectional view along the cross-section 24C-24C in FIG. 24A. As illustrated in FIGS. 24A through 24C, after performing CMP process to remove excessive metal materials outside the contact openings 310, the mask layer 306 are removed.

In one or more embodiments, the source/drain contacts 270 are overlaps at least one of the nanostructures 203 in the regions 203N and 203P. In FIG. 24A, one of the source/drain contacts 270 extends across the nanostructures in the regions 203N and 203P and can be referred to as a common source/drain contact 270.

Referring to FIGS. 24A and 24B. FIG. 24B illustrates a cross-section along the nanostructure 203 in the region 203P. In FIGS. 24A and 24B, a common source/drain region 232 on the nanostructures 203 in the region 203P is free of the source/drain contacts 270. In one or more embodiments of the present disclosure, the common source/drain region 232 in the region 203P connects the adjacent transistors formed by the nanostructures 203 and the gate structures 240 in the region 203P in series connection. The adjacent transistors in series connection form a cascade device, and the common source/drain region 232 of the cascade device is free from the source/drain contacts 270. The contact-free common source/drain regions 232 connecting the adjacent transistors in series connection may have low resistance for the current flow through the adjacent nanostructures 203.

In some embodiments, as illustrated in FIG. 24B, the source/drain contact 270 extends into the source/drain region 232 has a depth D2 from a top surface of the topmost nanostructure 204C to a bottom surface of the silicide region 272, wherein the depth D2 is greater than a depth D1 from the top surface of the topmost nanostructure 204C to a top surface of the nanostructure 204B. In other words, the bottom surface of the silicide region 272 is lower than the top surface of the nanostructure 204B. In some embodiments, a difference between the depths D1 and D2 is in a range from about 0 nm to about 50 nm. The deep MD (including the source/drain contact 270 and the silicide region 272) is to reduce parasitic resistance due to current crowding within the source/drain region 232 and to reduce the contact resistance.

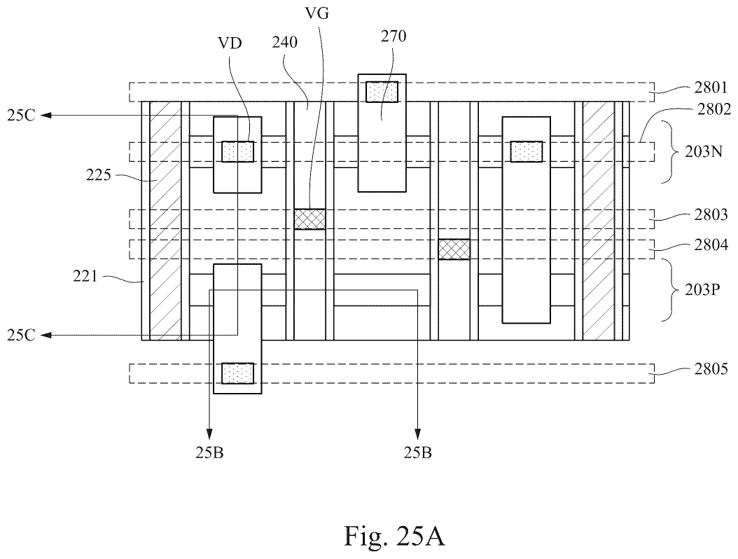

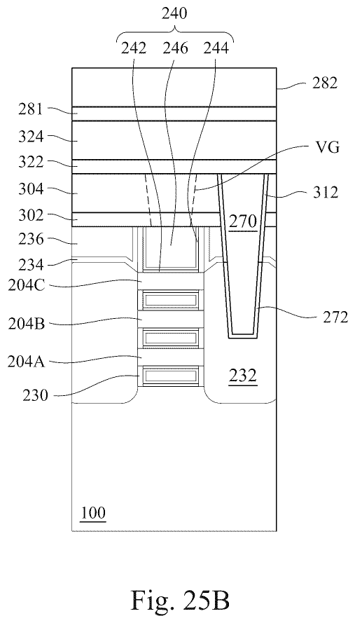

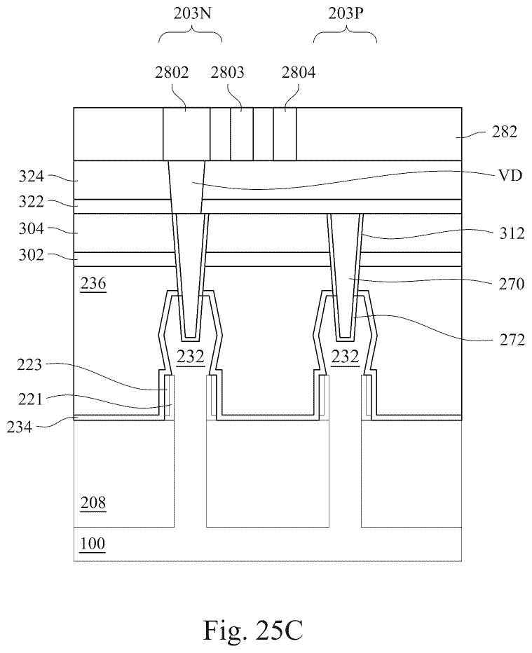

Reference is made to FIGS. 25A through 25C. FIG. 25A illustrates a top view of formation of contact vias VD and VG and the metal lines 280. FIG. 25B illustrates a cross-sectional view along the cross-section 25B-25B in FIG. 25A. FIG. 25C illustrates a cross-sectional view along the cross-section 25C-25C in FIG. 25A.

An interconnect structure including vias VG is formed within the CESL 302 and the ILD layer 304 to electrically connect to the gate the CESL 322 and the ILD layer 324 to electrically connect to the gate metal layer 246 of the gate structures 240. FIG. 25B illustrates the gate vias VG on the gate structure 240 in the cross-section 25B-25B by dash-lines.

As illustrated in FIGS. 25A through 25C, a CESL 322 is formed over the ILD layer 304 and the source/drain contacts 270. The CESL 322 may be formed of a dielectric material, such as silicon nitride, silicon oxide, silicon oxynitride, or the like. The CESL 322 may be formed by any suitable method, such as CVD, ALD, or the like. An inter-layer dielectric (ILD) layer 324 can be deposited over the CESL 322. The ILD layer 324 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. The CESL 322 may have a high etching selectivity from the etching of the ILD layer 324. In some embodiments, a thickness of the CESL 322 is less than a thickness of the ILD layer 324.

Subsequently, an interconnect structure including vias VD can be formed within the CESL 322 and the ILD layer 324 to electrically connect to the corresponding source/drain contacts 270 and the gate structures 240. The interconnect structure further includes the metal lines 2801, 2802, 2803, 2804 and 2805 respectively connected to the source/drain regions 232 and the gate structures 240 through the corresponding vias VD or the corresponding via VG. The interconnect structure may further include vias (not illustrated) connecting the gate via VG to the overlapping metal lines. For clarify, the metal lines 2801, 2802, 2803, 2804 and 2805 connects the underlying vias VD or VG are illustrated in FIG. 25A. In some embodiments, the metal lines 2801, 2802, 2803, 2804 and 2805 extend along the lengthwise direction of the nanostructures 203. A CESL 281 is formed over the ILD layer 324. Also included in the interconnect structure is an inter-metal dielectric (IMD) layer 282 over the CESL 281. The IMD layer 282 may provide electrical insulation as well as structural support for the various features of the interconnect structure. In some embodiments, the IMD layer 282 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, the IMD layer 282 may be made of an oxide, nitride, the like, or combinations thereof. The gate dielectrics 244 of the gate structures 240 have higher k-value than that of at least one of dielectric layers the gate spacers 221 and 223, the ILD layer 304 and the IMD layer 282.

As an example to form the metal lines 2801, 2802, 2803, 2804 and 2805 in the interconnect structure, trenches/openings for the metal lines 2801, 2802, 2803, 2804 and 2805 are formed through the IMD layer 282 and the CESL 281. The trenches/openings may be formed using acceptable photolithography and etching techniques. A liner (not separately illustrated), such as a diffusion barrier interface layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the IMD layer 282. The remaining liner and conductive material form the metal lines 2801, 2802, 2803, 2804 and 2805 in the trenches/openings. The metal lines 2801, 2802, 2803, 2804 and 2805 may be formed in distinct processes, or may be formed in the same process. In some embodiments, material and manufacturing method of the conductive lines (not shown) in other metallization layers are substantially the same as those of the conductive line in the first metallization layer.

The metal line 2801 is interchangeably referred to as a Vdd line that is provided with a power supply voltage Vdd. In FIG. 25A, the metal line 2801 may be connected to the common source/drain contact 270 over the nanostructure 203 by the underlying contact via VD in the region 203N. As illustrated in FIGS. 25A and 25C, the metal line 2802 connects the source/drain contacts 270 between the gate structures 240 and the dielectric-based gates 225 by the underlying contact vias VD in the region 203N. In FIG. 25A, the metal lines 2803 and 2804 connected to the gate structures by the underlying gate vias VG. The metal line 2805 may be interchangeably referred to as a Vss line that is an electrical ground.

As illustrated in FIGS. 25A through 25C, the source/drain contacts 270 are surrounded by the CESL 234 and the ILD layer 236. In some embodiments, conductivity of the source/drain contacts 270 is greater than that of source/drain regions 232 and the silicide regions 272. In some embodiments, along the lengthwise direction of the nanostructures 203, the CESL 234 is thinner than the ILD layer 236. In some embodiments, along a vertical direction, the ILD layer 236 is thicker than the ILD layer 304. In some embodiments, the source/drain contacts 270 are spaced apart from the gate structures 240 by the CESL 234, the ILD layer 236, and the gate spacer 221. In some embodiments, a non-linear interface is between one of the ILD layers 236 and one of the source/drain contacts 270. In some embodiments, a dielectric constant of the gate dielectric 244 is at least twice a dielectric constant of the ILD layer 236. In some embodiments, a dielectric constant of the gate dielectric 244 of the gate structure 240 is greater than a dielectric constant of one of the ILD layers 304 and 324. In some embodiments, the ILD layers 304 and 324 have different dielectric constant.

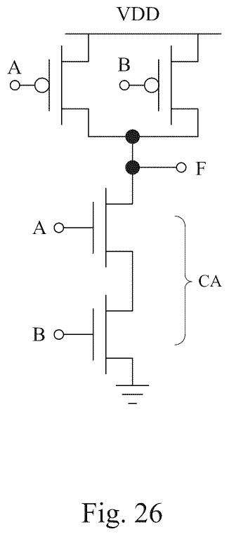

FIG. 26 schematically illustrates a circuit diagram of FIGS. 25A through 25C, in accordance with some embodiments. For example, the circuit diagram in FIG. 26 can be an NAND cell. Referring to FIGS. 25A and 26, the metal line 2801 is interchangeably referred to as a Vdd line and connected to the source/drain contact 270 on the common source/drain regions 232 by the contact via VD in the region 203N. The metal line 2802 connects the contact vias VD in the region 203N, wherein one of the source/drain contacts 270 connected to the contact vias VD, in which the metal line 2802 is connected to, is a common source/drain contact extending across the nanostructures 203 in the regions 203N and 203P. The metal line 2802 corresponds to the node F in FIG. 26. The metal line 2803 is connected to one of the gate structures 240 and corresponds to the node A in FIG. 26. The metal line 2804 is connected to one of the gate structures 240 and corresponds to the node B in FIG. 26. The metal line 2805 is interchangeably referred to as a Vss line that is an electrical ground. In one or more embodiments, the circuit diagram in FIG. 26 includes a cascade device CA with transistor in series connection. As illustrated in FIGS. 25A and 26, the cascade device CA are in the region 203P and free from the source/drain contacts 270.

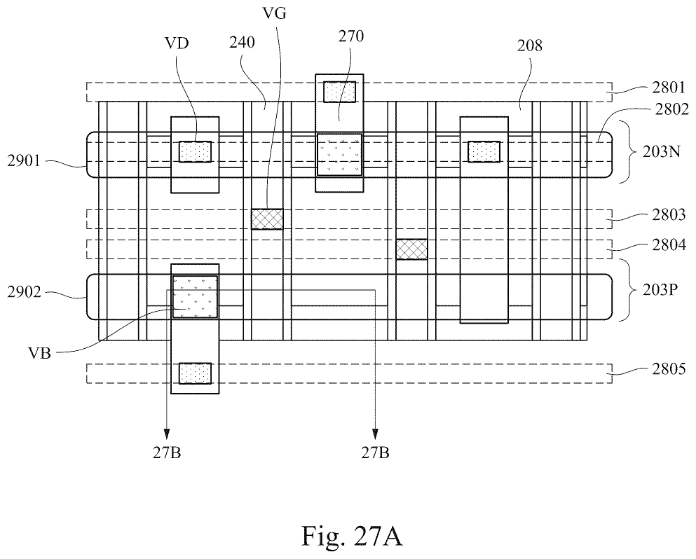

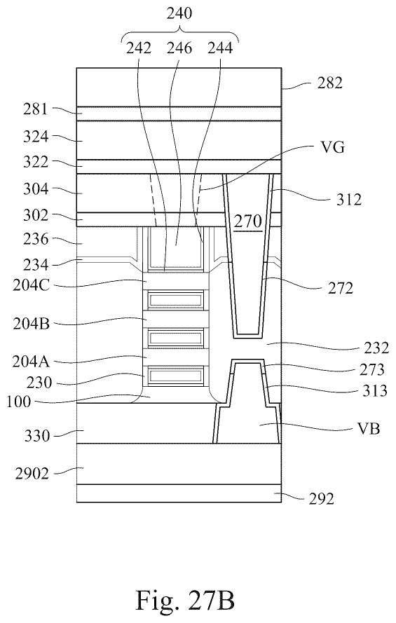

Reference is made to FIGS. 27A and 27B. FIGS. 27A and 27B illustrate a semiconductor structure, in accordance with some embodiments. FIG. 27A illustrates a top view of the semiconductor structure. FIG. 27B illustrates a cross-sectional view along the cross-section 27B-27B in FIG. 27A.

As illustrated in FIGS. 27A and 27B, the structure in FIGS. 27A and 27B may be substantially the same as the structure in FIG. 25A through 25C, except that back-side contact vias VB are formed under the source/drain contacts 270 connected to the Vdd metal line 2801 and the Vss metal line 2805 and back-side power lines 2901 and 2902 connected to the overlapping back-side contact vias VB. The metal lines 2801 and 2901 are referred to as a dual-side Vdd metal line. The metal lines 2801 and 2901 are referred to as a dual-side Vss metal line.

In some embodiments, a polish process is performed to a backside of the substrate 100, followed by forming an oxide layer 330 over the bottom of the source/drain region 232 and the remaining substrate 100. The backside vias VB are then formed within the oxide layer 330 and extend into the source/drain region 232. In some embodiments, formation of the backside vias VB may include two-step etching. For example, formation of the backside vias VB include forming a first trench in the oxide layer and forming a second trench from a bottom of the first trench to the source/drain region 232, wherein the first trench is wider than the second trench. In FIG. 27B, barrier interface layers 313 are formed on the sidewalls of the oxide layer 330. In some embodiments, the barrier interface layers 313 are formed through the un-doped semiconductor layers 231 and the dielectric layer 233 (see FIG. 12D), so that top surfaces of the barrier interface layers 313 are higher than a bottom surface of the gate structure 240 under the bottommost nanostructure 204A. In some embodiments, the barrier interface layers 312 may include SiN, SiON, SiCN, SiCON, SiCO, high-k dielectric such as HfO, AlO, or composition of multiple layers. The backside vias VB may include metal-filled material similar to the material of the source/drain contact 270. As illustrated in FIG. 27B, a silicide region 273 is formed between the source/drain region 232 and a top surface of the backside via VB. An IMD layer 292 is formed over the oxide layer 300 following formation of the backside vias VB. The metal lines 2901 and 2902 are formed in the IMD layer 292 and connected in the overlapping backside vias VB.

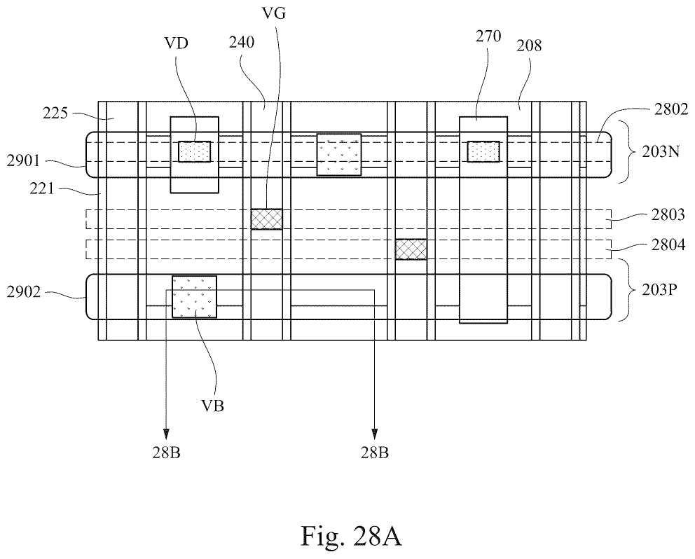

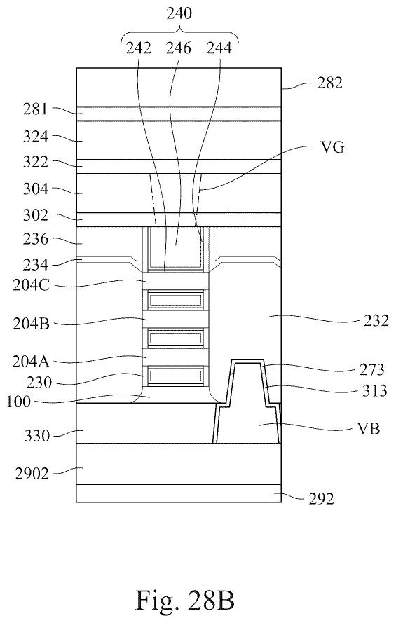

Reference is made to FIGS. 28A and 28B. FIGS. 28A and 28B illustrates a semiconductor structure, in accordance with some embodiments. FIG. 28A illustrates a top view of the semiconductor structure. FIG. 28B illustrates a cross-sectional view along the cross-section 28B-28B in FIG. 28A.

As illustrated in FIGS. 28A and 28B, the structure in FIGS. 28A and 28B may be substantially the same as the structure in FIGS. 27A and 27B, except that the front-side metal lines 2801 and 2805 and the underlying the contact vias VD are omitted. The backside metal line 2901 is referred to as a back-side Vdd metal line. The backside metal line 2902 is referred to as a back-side Vss metal line.

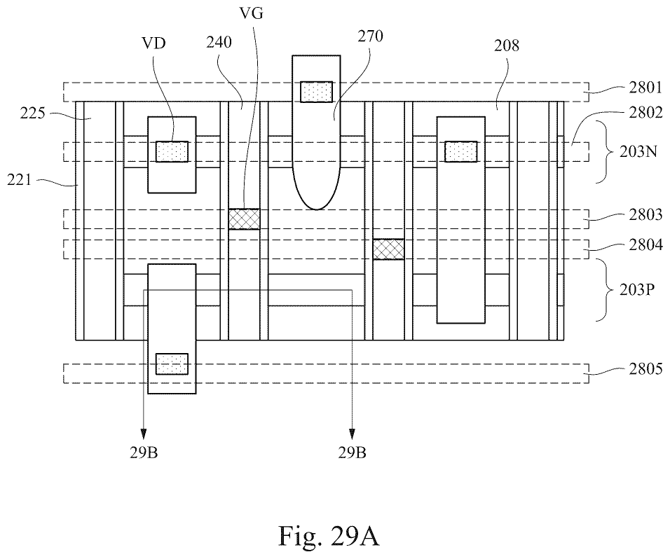

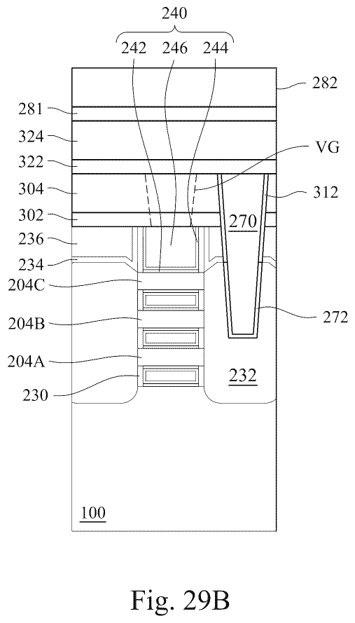

Reference is made to FIGS. 29A and 29B. FIGS. 29A and 29B illustrate a semiconductor structure, in accordance with some embodiments. FIG. 29A illustrates a top view of the semiconductor structure. FIG. 29B illustrates a cross-sectional view along the cross-section 29B-29B in FIG. 29A.

As illustrated in FIGS. 29A and 29B, the structure in FIGS. 29A and 29B may be substantially the same as the structure in FIGS. 25A through 25C, except that the source/drain contacts 270 connected to the metal line 2801 has a nature end. From the top view as illustrated in FIG. 29A, the source/drain contacts 270 connected to the metal line 2801 extends along the lengthwise direction of the gate structures 240 and has a curved or rounding profile protruding towards the cascade device. Since MD does not need to be formed on the common source/drain regions 232 of the cascade device on the nanostructure 203 in the region 203P, the occupied space for forming the source/drain contacts 270 connected to the metal line 2801 can be increased to have the nature end.

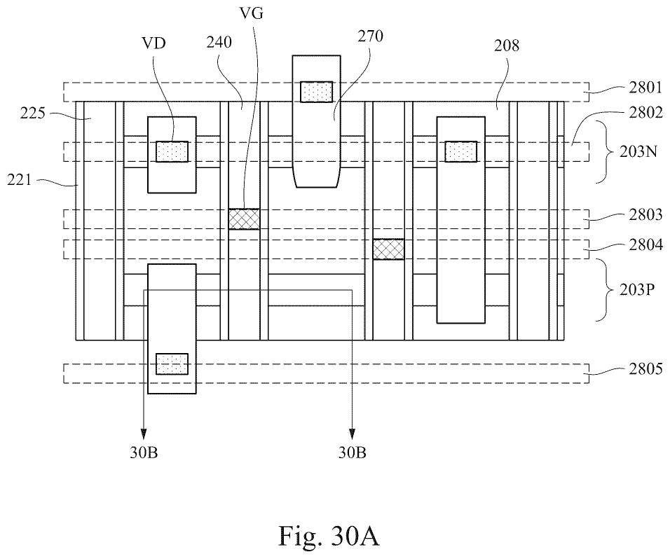

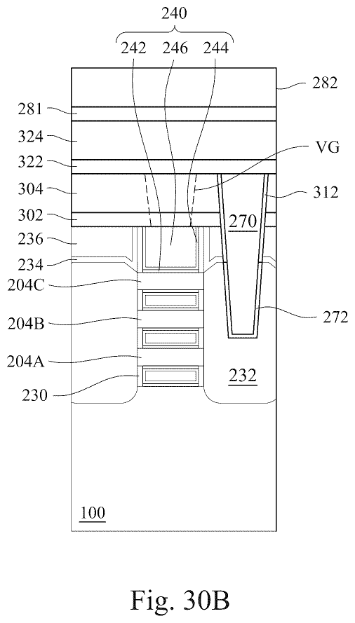

Reference is made to FIGS. 30A and 30B. FIGS. 30A and 30B illustrate a semiconductor structure, in accordance with some embodiments. FIG. 30A illustrates a top view of the semiconductor structure. FIG. 30B illustrates a cross-sectional view along the cross-section 30B-30B in FIG. 30A.

As illustrated in FIGS. 30A and 30B, the structure in FIGS. 30A and 30B may be substantially the same as the structure in FIGS. 29A and 29B, except that the nature end of the source/drain contacts 270 connected to the metal line 2801 is cut. From the top view as illustrated in FIG. 30A, the source/drain contacts 270 connected to the metal line 2801 have a profile with curves connected to the straight line end.

According to one or more embodiments of the present disclosure, a method includes a number of operations. A first channel region and a second channel region are formed over the substrate. An isolation feature is formed over the substrate and between the first and second channel regions. A first source/drain feature is formed and interfaces a sidewall of the first channel region. A source/drain contact is formed over the first source/drain feature. A second source/drain feature is formed and interfaces a sidewall of the second channel region, wherein the second source/drain feature is free of any source/drain contact. An etch stop layer is formed and continuously extends from over the first source/drain feature to over the second source/drain feature. An interlayer dielectric (ILD) layer is formed over the etch stop layer, wherein a top surface of the isolation feature is spaced apart from the ILD layer by the etch stop layer. In one or more embodiments of the present disclosure, the method further includes forming an interface layer between the contact feature and the ILD layer. In some embodiments, wherein the interface layer comprises silicon nitride. In one or more embodiments of the present disclosure, the method further includes forming a backside contact feature at a backside of the first source/drain feature. In one or more embodiments of the present disclosure, the method further includes forming a backside interface layer on the backside contact feature. In one or more embodiments of the present disclosure, the contact feature has a rounding profile. In one or more embodiments of the present disclosure, the method further includes forming a gate structure across the first and second channel regions.

According to one or more embodiments of the present disclosure, a method includes a number of operations. A first region including a first active region and a first base region is formed. A second region including a second active region and a second base region is formed. An isolation feature is formed and disposed between the first base region and the second base region, wherein the isolation feature interfaces a sidewall of the first base region and a sidewall of the second base region. An epitaxial source/drain feature is formed over the first active region. A dielectric layer is formed over the epitaxial source/drain feature. A contact feature is formed and extends through the dielectric layer, wherein the contact feature is surrounded by the dielectric layer, the contact feature is spaced apart from the dielectric layer by an interface layer. A contact-free epitaxial source/drain feature is formed over the second active region. In one or more embodiments of the present disclosure, wherein the contact feature has a curved profile protrudes toward the second active region from a top view. In one or more embodiments of the present disclosure, the method further includes forming a backside contact feature at a backside of the epitaxial source/drain feature. In one or more embodiments of the present disclosure, the interface layer comprises silicon nitride. In one or more embodiments of the present disclosure, the method further includes a top surface of the epitaxial source/drain feature is more concave than a top surface of the contact-free epitaxial source/drain feature. In one or more embodiments of the present disclosure, the method further includes the contact-free epitaxial source/drain feature has a different conductive type from the epitaxial source/drain feature.

According to one or more embodiments of the present disclosure, a semiconductor structure includes a first active region and a second active region over a substrate; a gate structure over the first active region and the second active region; a first epitaxial source/drain feature and a second epitaxial source/drain feature on the first active region and at opposite sides of the gate structure; dielectric layers over the first and second epitaxial source/drain features; a first contact feature over the first epitaxial source/drain feature and extending through the dielectric layers and a second contact feature extending over the second epitaxial source/drain feature and across the first and second active regions. The contact feature is surrounded by the dielectric layers. The contact feature is spaced apart from the dielectric layers by an interface layer. The contact feature is spaced apart from the dielectric layers by an interface layer. From a top view, an end of the first contact feature is more curved than an end of the second contact feature on the second active region. In one or more embodiments of the present disclosure, the first contact feature has a curved profile protruding towards a direction different from a lengthwise direction of the first active region. In one or more embodiments of the present disclosure, the semiconductor structure further includes a contact-free epitaxial source/drain feature having a different conductive type from the first epitaxial source/drain feature. In some embodiments, the contact-free epitaxial source/drain feature is on the second active region. In one or more embodiments of the present disclosure, a bottom surface of the first contact feature is less than at least portion of the gate structure. In one or more embodiments of the present disclosure, the interface layer comprises silicon nitride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first channel region and a second channel region over a substrate;
forming an isolation feature over the substrate and between the first channel region and the second channel region;
forming a first source/drain feature interfacing a sidewall of the first channel region;
forming a source/drain contact over the first source/drain feature;
forming a second source/drain feature interfacing a sidewall of the second channel region, wherein the second source/drain feature is free of any source/drain contact;
forming an etch stop layer continuously extending from over the first source/drain feature to over the second source/drain feature;
forming an interlayer dielectric (ILD) layer over the etch stop layer, wherein a top surface of the isolation feature is spaced apart from the ILD layer by the etch stop layer.

2. The method of claim 1, further comprising:
forming an interface layer between the contact feature and the ILD layer.

3. The method of claim 2, wherein the interface layer comprises silicon nitride.

4. The method of claim 1, further comprising:
forming a backside contact feature at a backside of the first source/drain feature.

5. The method of claim 4, further comprising:
forming a backside interface layer on the backside contact feature.

6. The method of claim 1, wherein the contact feature has a rounding profile.

7. The method of claim 1, further comprising:
forming a gate structure across the first and second channel regions.

8. A method comprising:
forming a first region comprising a first active region and a first base region;
forming a second region comprising a second active region and a second base region;
forming an isolation feature disposed between the first base region and the second base region, wherein the isolation feature interfaces a sidewall of the first base region and a sidewall of the second base region;
forming an epitaxial source/drain feature over the first active region;
forming a dielectric layer over the epitaxial source/drain feature;
forming a contact feature extending through the dielectric layer, wherein the contact feature is surrounded by the dielectric layer, the contact feature is spaced apart from the dielectric layer by an interface layer; and
forming a contact-free epitaxial source/drain feature over the second active region.

9. The method of claim 8, wherein the contact feature has a curved profile protrudes toward the second active region from a top view.

10. The method of claim 8, further comprising:
forming a backside contact feature at a backside of the epitaxial source/drain feature.

11. The method of claim 8, wherein the interface layer comprises silicon nitride.

12. The method of claim 8, further comprising:
forming a gate structure across the first and second active region.

13. The method of claim 8, wherein a top surface of the epitaxial source/drain feature is more concave than a top surface of the contact-free epitaxial source/drain feature.

14. The method of claim 8, wherein the contact-free epitaxial source/drain feature has a different conductive type from the epitaxial source/drain feature.

15. A semiconductor structure comprising:
a first active region and a second active region over a substrate;
a gate structure over the first active region and the second active region;
a first epitaxial source/drain feature and a second epitaxial source/drain feature on the first active region and at opposite sides of the gate structure;
dielectric layers over the first and second epitaxial source/drain features;
a first contact feature over the first epitaxial source/drain feature and extending through the dielectric layers, wherein the contact feature is surrounded by the dielectric layers, the contact feature is spaced apart from the dielectric layers by an interface layer;
a second contact feature extending over the second epitaxial source/drain feature and across the first and second active regions, wherein from a top view, an end of the first contact feature is more curved than an end of the second contact feature on the second active region.

16. The semiconductor structure of claim 15, wherein the first contact feature has a curved profile protruding towards a direction different from a lengthwise direction of the first active region.

17. The semiconductor structure of claim 15, further comprising:
a contact-free epitaxial source/drain feature having a different conductive type from the first epitaxial source/drain feature.

18. The semiconductor structure of claim 17, wherein the contact-free epitaxial source/drain feature is on the second active region.

19. The semiconductor structure of claim 15, wherein a bottom surface of the first contact feature is less than at least portion of the gate structure.

20. The semiconductor structure of claim 15, wherein the interface layer comprises silicon nitride.
